(19) United States
(12) Patent Application Publication
(10) Pub. No.: US 2022/0181374 A1
(43) Pub. Date: Jun. 9, 2022

(54) SENSOR CHIP AND ELECTRONIC APPARATUS

(71) Applicant: SONY SEMICONDUCTOR SOLUTIONS CORPORATION, Kanagawa (JP)

(72) Inventors: Kyosuke ITO, Kanagawa (JP); Toshifumi WAKANO, Kanagawa (JP); Yusuke OTAKE, Kanagawa (JP)

(73) Assignee: SONY SEMICONDUCTOR SOLUTIONS CORPORATION, Kanagawa (JP)

(21) Appl. No.: 17/436,765

(22) PCT Filed: Feb. 13, 2020
(86) PCT No.: PCT/JP2020/005431

§ 371 Date: Sep. 7, 2021

(30) Foreign Application Priority Data
Mar. 19, 2019 (JP) 2019-050884

(51) Int. Cl. H01L 27/146

(52) U.S. Cl. CPC H01L 27/14629; H01L 27/14643; H01L 27/14623

(57) ABSTRACT

A sensor chip according to an embodiment of the present disclosure includes: a photoelectric conversion section including a multiplication region that avalanche-multiplies carriers by a high electric field region; a light-condensing section that condenses incident light toward the photoelectric conversion section; and a pixel array in which a plurality of pixels each including the photoelectric conversion section and the light-condensing section are arranged in array and at least one of a structure of the photoelectric conversion section or a structure of the light-condensing section is changed stepwise from a middle part toward an outer peripheral part.

### TECHNICAL FIELD

The present disclosure relates to a sensor chip and an electronic apparatus including the sensor chip.

### BACKGROUND ART

An avalanche photodiode (APD; Avalanche Photodiode) has a Geiger mode to operate at a bias voltage higher than a breakdown voltage and a linear mode to operate at a slightly high bias voltage near the breakdown voltage. The APD in the Geiger mode is also called a single photon avalanche diode (SPAD; Single Photon Avalanche Diode).

The SPAD is a device that is able to detect a single photon for each pixel by avalanche-multiplying carriers generated by photoelectric conversion in a high electric field P-N junction region provided for each pixel.

PTL 1 discloses a radiation detection apparatus provided with a photodetection element array including a plurality of cells each including an avalanche photodiode, with a lens provided for each cell.

### CITATION LIST

### Patent Literature

PTL 1: Japanese Unexamined Patent Application Publication No. 2015-179087

### SUMMARY OF THE INVENTION

It is desired, in a pixel array including a plurality of SPADs, to equalize characteristics of a middle part and an outer peripheral part of the pixel array.

It is desirable to provide a sensor chip that makes it possible to equalize characteristics of a middle part and an outer peripheral part of a pixel array, and an electronic apparatus including such a sensor chip.

A sensor chip according to an embodiment of the present disclosure includes: a photoelectric conversion section including a multiplication region that avalanche-multiplies carriers by a high electric field region; a light-condensing section that condenses incident light toward the photoelectric conversion section; and a pixel array in which a plurality of pixels each including the photoelectric conversion section and the light-condensing section are arranged in array and at least one of a structure of the photoelectric conversion section or a structure of the light-condensing section is changed stepwise from a middle part toward an outer peripheral part.

An electronic apparatus according to an embodiment of the present disclosure includes an optical system, a sensor chip, and a signal processing circuit, and includes, as the sensor chip, the above-described sensor chip according to an embodiment of the present disclosure.

According to the sensor chip of an embodiment of the present disclosure and the electronic apparatus of an embodiment of the present disclosure, at least one of the structure of the photoelectric conversion section or the structure of the light-condensing section is changed stepwise from the middle part toward the outer peripheral part in the plurality of pixels of the pixel array. This allows light having obliquely entered a light incident surface to be closer to the multiplication region in a pixel in the outer peripheral part.

### BRIEF DESCRIPTION OF THE DRAWINGS

FIG. 1 illustrates an example of a planar configuration of a sensor chip according to a first embodiment of the present disclosure.

FIG. 2 illustrates an example of a cross-sectional configuration of the sensor chip of FIG. 1 along I-I′ and II-II′.

FIG. 3A illustrates an example of a cross-sectional configuration of the sensor chip of FIG. 1 along I-I′.

FIG. 3B illustrates an example of a cross-sectional configuration of the sensor chip of FIG. 1 along II-II′.

FIG. 4A illustrates an example of a cross-sectional configuration of the sensor chip of FIG. 1 in a manufacturing process.

FIG. 4B illustrates an example of a cross-sectional configuration in a manufacturing process subsequent to FIG. 4A.

FIG. 4C illustrates an example of a cross-sectional configuration in a manufacturing process subsequent to FIG. 4B.

FIG. 4D illustrates an example of a cross-sectional configuration in a manufacturing process subsequent to FIG. 4C.

FIG. 4E illustrates an example of a cross-sectional configuration in a manufacturing process subsequent to FIG. 4D.

FIG. 5 illustrates an example of a cross-sectional configuration of a sensor chip according to a reference embodiment.

FIG. 6 illustrates an example of a cross-sectional configuration of a sensor chip according to Modification Example A.

FIG. 7 illustrates an example of a cross-sectional configuration of a sensor chip according to Modification Example B.

FIG. 8 illustrates an example of a cross-sectional configuration of a sensor chip according to Modification Example C.

FIG. 9 illustrates another example of the cross-sectional configuration of the sensor chip of FIG. 1.

FIG. 10 illustrates an example of a cross-sectional configuration of a sensor chip according to Modification Example D.

FIG. 11A illustrates an example of a cross-sectional configuration of the sensor chip of FIG. 10 in a manufacturing process.

FIG. 11B illustrates an example of a cross-sectional configuration in a manufacturing process subsequent to FIG. 11A.

FIG. 11C illustrates an example of a cross-sectional configuration in a manufacturing process subsequent to FIG. 11B.

FIG. 11D illustrates an example of a cross-sectional configuration in a manufacturing process subsequent to FIG. 11C.

FIG. 11E illustrates an example of a cross-sectional configuration in a manufacturing process subsequent to FIG. 11D.

FIG. 11F illustrates an example of a cross-sectional configuration in a manufacturing process subsequent to FIG. 11E.

FIG. 12 illustrates an example of a cross-sectional configuration of a sensor chip according to Modification Example E.

FIG. 13 illustrates an example of a cross-sectional configuration of a sensor chip according to Modification Example F.

FIG. 14 illustrates an example of a cross-sectional configuration of a sensor chip according to Modification Example G.

FIG. 15 illustrates an example of a cross-sectional configuration of a sensor chip according to Modification Example H.

FIG. 16 illustrates an example of a cross-sectional configuration of a middle pixel of a sensor chip according to Modification Example I.

FIG. 17 illustrates an example of a cross-sectional configuration of an outer peripheral pixel of the sensor chip of FIG. 16.

FIG. 18 illustrates an example of a cross-sectional configuration of a sensor chip according to Modification Example J.

FIG. 19 illustrates an example of a cross-sectional configuration of a sensor chip according to Modification Example K.

FIG. 20 illustrates an example of a cross-sectional configuration of a sensor chip according to Modification Example L.

FIG. 21 illustrates an example of a cross-sectional configuration of a middle pixel of a sensor chip according to Modification Example M.

FIG. 22 illustrates an example of a cross-sectional configuration of an outer peripheral pixel of the sensor chip of FIG. 21.

FIG. 23 illustrates an example of a cross-sectional configuration of a sensor chip according to Modification Example N.

FIG. 24 illustrates an example of a planar configuration of a sensor chip according to Modification Example O.

FIG. 25 illustrates an example of a cross-sectional configuration of a middle pixel of the sensor chip of FIG. 24.

FIG. 26 illustrates an example of a cross-sectional configuration of an outer peripheral pixel of the sensor chip of FIG. 24.

FIG. 27 illustrates an example of a cross-sectional configuration of a sensor chip according to Modification Example P.

FIG. 28A illustrates an example of a cross-sectional configuration of a sensor chip according to a second embodiment of the present disclosure.

FIG. 28B illustrates an example of a cross-sectional configuration of an outer peripheral pixel of the sensor chip of FIG. 28A.

FIG. 29 illustrates an example of a cross-sectional configuration of the sensor chip in FIG. 28A in a manufacturing process.

FIG. 30 illustrates an example of a cross-sectional configuration of a sensor chip according to Modification Example Q.

FIG. 31 illustrates an example of a cross-sectional configuration of a sensor chip according to Modification Example R.

FIG. 32 illustrates an example of a cross-sectional configuration of a sensor chip according to Modification Example S.

FIG. 33 is a block diagram illustrating an example of a schematic configuration of an electronic apparatus including the sensor chip according to any of the foregoing embodiments and modification examples thereof.

FIG. 34 is a block diagram depicting an example of schematic configuration of a vehicle control system.

FIG. 35 is a diagram of assistance in explaining an example of installation positions of an outside-vehicle information detecting section and an imaging section.

### MODES FOR CARRYING OUT THE INVENTION

Hereinafter, description is given in detail of embodiments of the present disclosure with reference to the drawings. It is to be noted that the description is given in the following order.

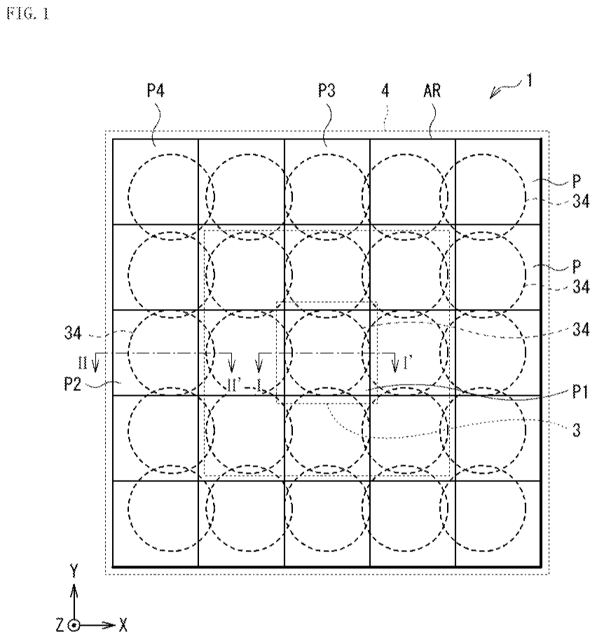

### 1. First Embodiment . . . FIGS. 1 to 4E

An example in which a pixel array including a plurality of SPADs is provided and a position of an on-chip lens relative to the SPAD is changed stepwise from a middle pixel toward an outer peripheral pixel of the pixel array

### 2. Modification Examples of First Embodiment

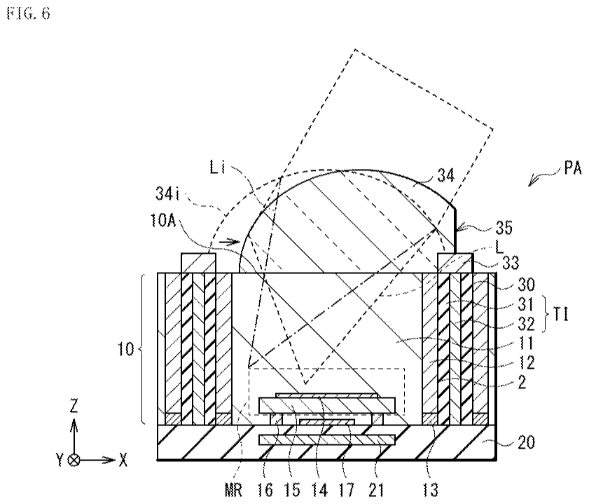

Modification Example A: An example in which a protruding portion of an on-chip lens toward a neighboring pixel is removed . . . FIG. 6

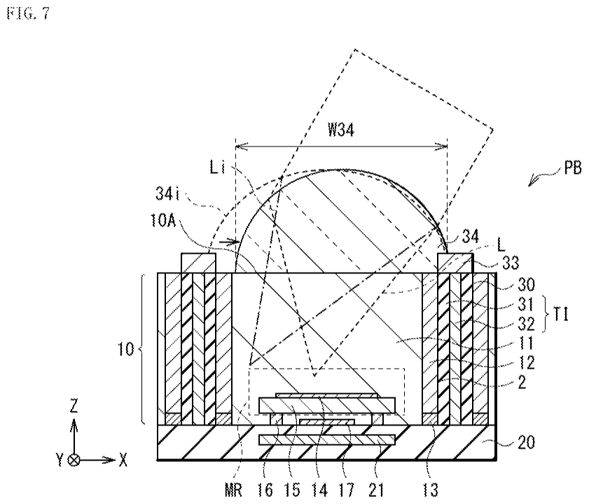

Modification Example B: An example in which a position of an on-chip lens relative to an SPAD and a size of the on-chip lens are changed stepwise from a middle pixel toward an outer peripheral pixel of a pixel array . . . FIG. 7

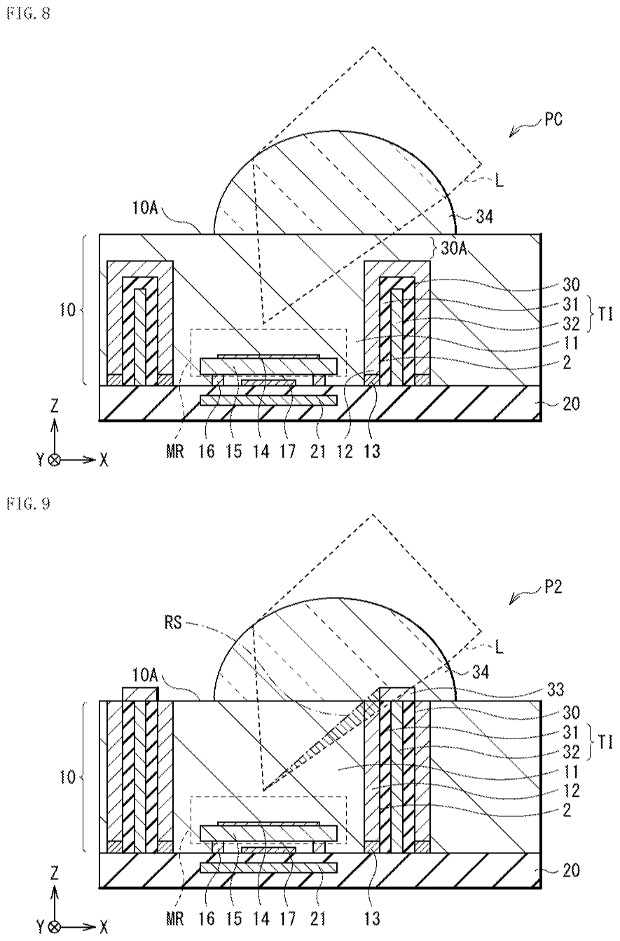

Modification Example C: An example in which an inter-pixel light-shielding film is not provided and a pixel separation film is not formed at a predetermined depth from a light incident surface of a semiconductor substrate . . . FIG. 8

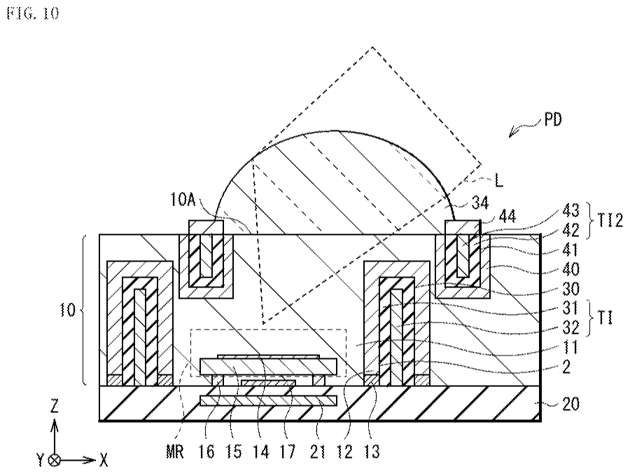

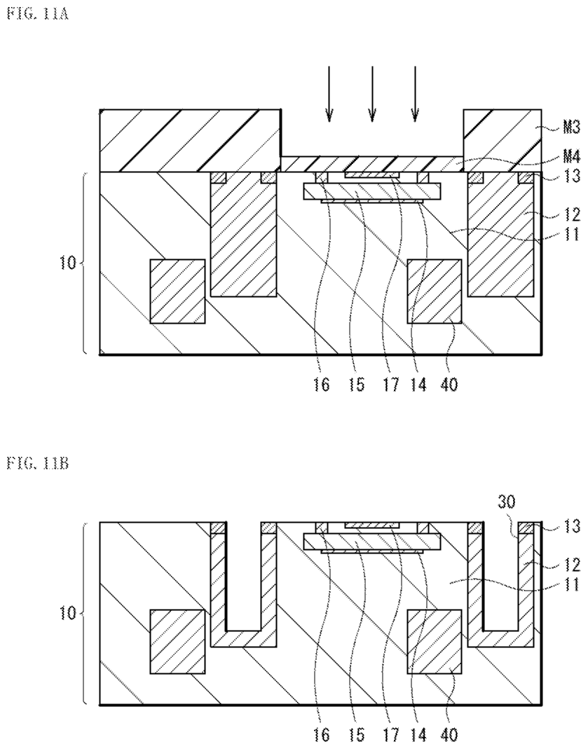

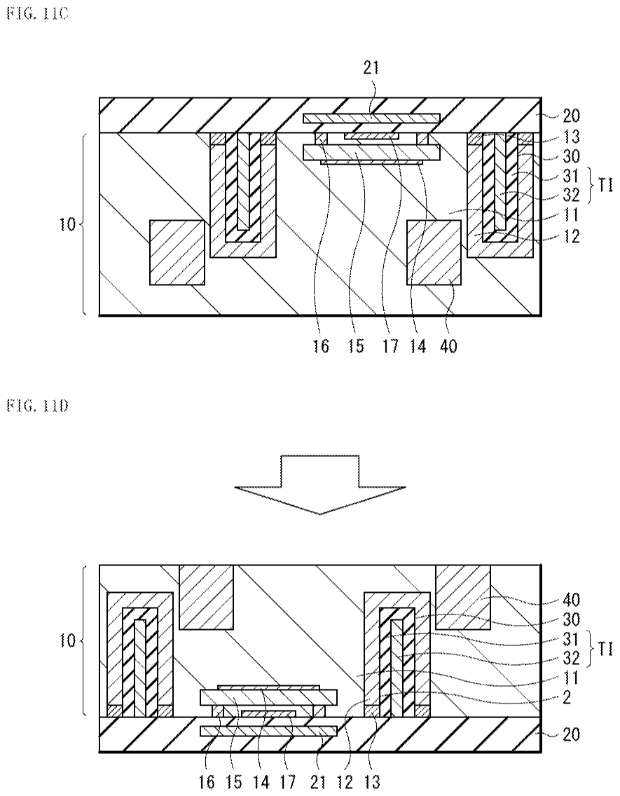

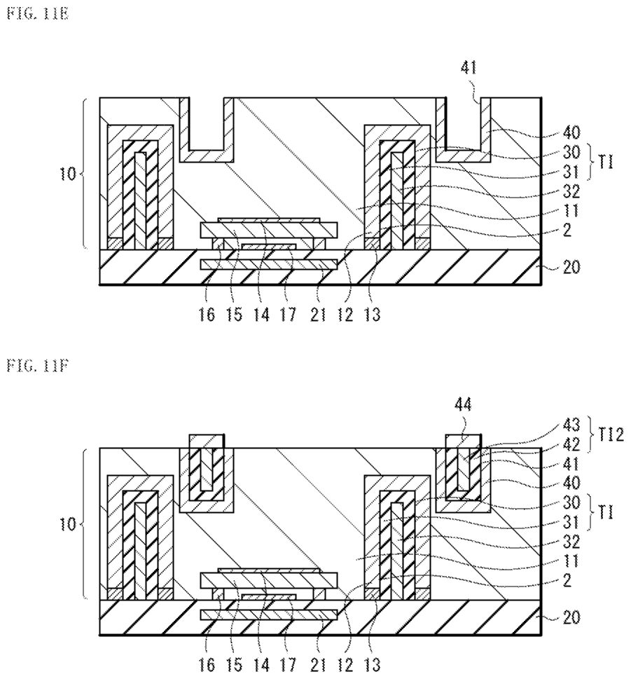

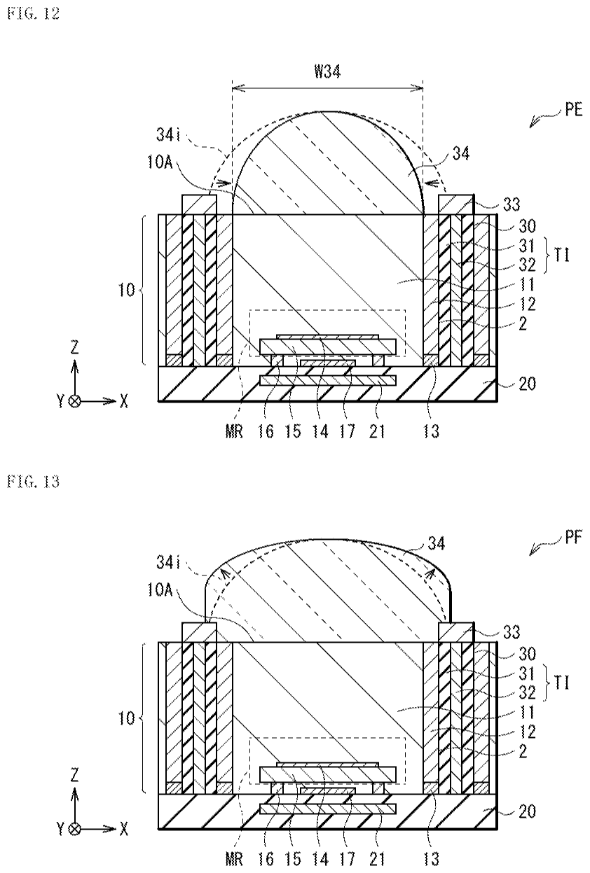

Modification Example D: An example in which a second pixel separation film and an inter-pixel light-shielding film in contact therewith are provided . . . FIGS. 10 to 11F

Modification Example E: An example in which a width of an on-chip lens in a direction parallel to a light incident surface is changed stepwise from a middle pixel toward an outer peripheral pixel of a pixel array . . . FIG. 12

Modification Example F: An example in which a curvature of an on-chip lens is changed stepwise from a middle pixel toward an outer peripheral pixel of a pixel array . . . FIG. 13

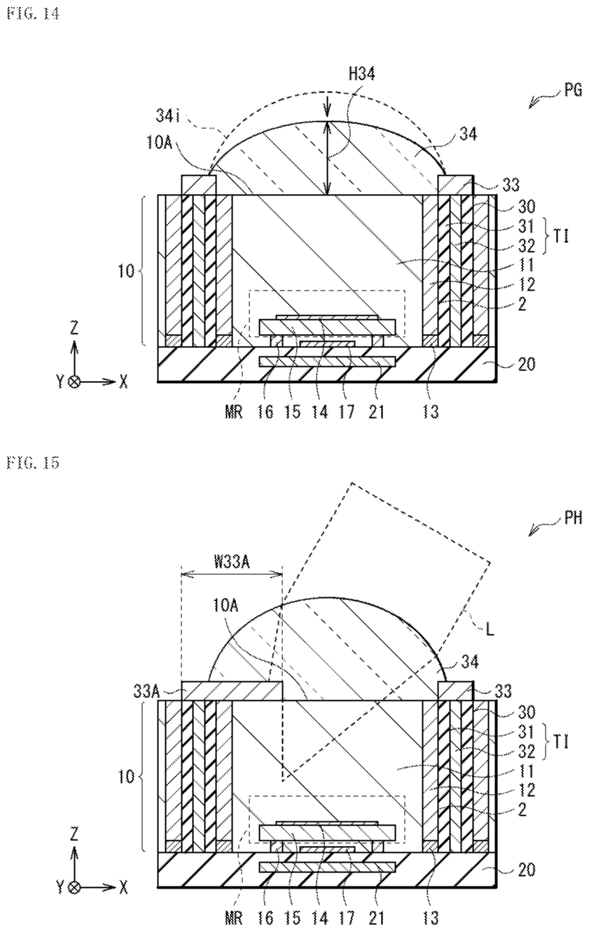

Modification Example G: An example in which a height of an on-chip lens is changed stepwise from a middle pixel toward an outer peripheral pixel of a pixel array . . . FIG. 14

Modification Example H: An example in which a line width of an inter-pixel light-shielding film provided, as a film, below an on-chip lens is changed stepwise from a middle pixel toward an outer peripheral pixel of a pixel array . . . FIG. 15

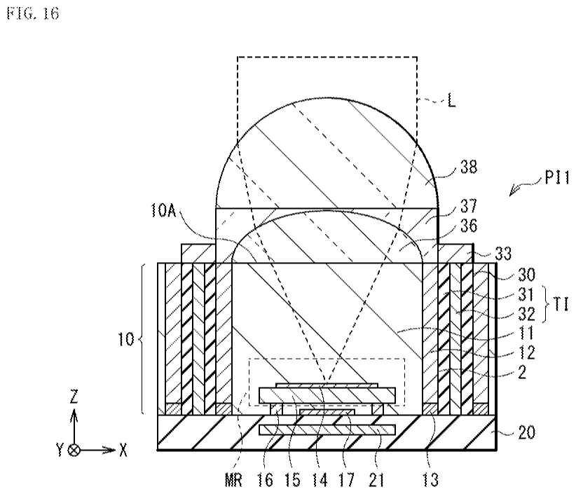

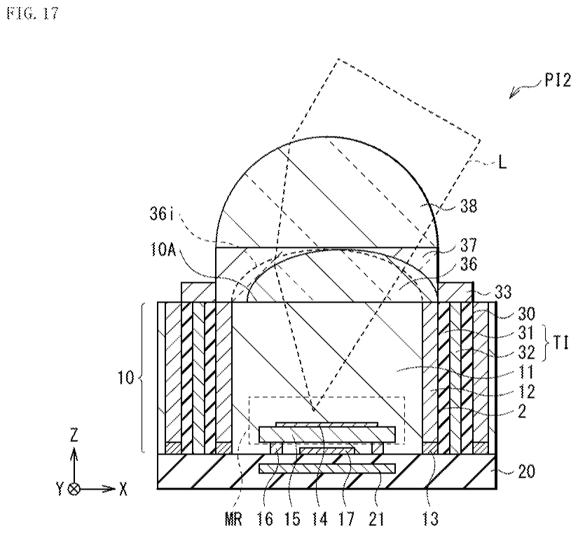

Modification Example I: An example in which a position of an inner lens relative to an SPAD is changed stepwise from a middle pixel toward an outer peripheral pixel of a pixel array . . . FIGS. 16 to 17

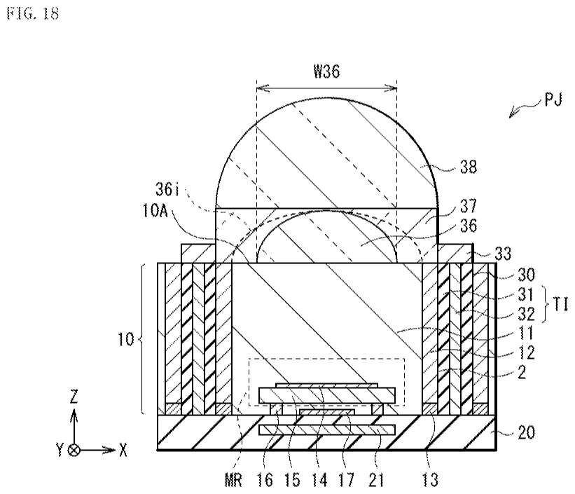

Modification Example J: An example in which a width of an inner lens in a direction parallel to a light incident surface is changed stepwise from a middle pixel toward an outer peripheral pixel of a pixel array . . . FIG. 18

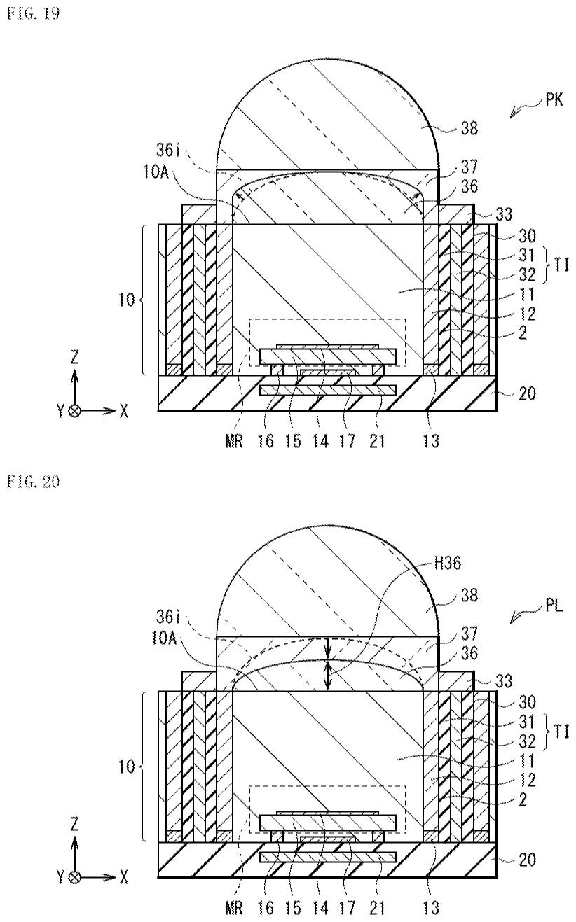

Modification Example K: An example in which a curvature of an inner lens is changed stepwise from a middle pixel toward an outer peripheral pixel of a pixel array . . . FIG. 19

Modification Example L: An example in which a height of an inner lens is changed stepwise from a middle pixel toward outer peripheral pixel of a pixel array . . . FIG. 20

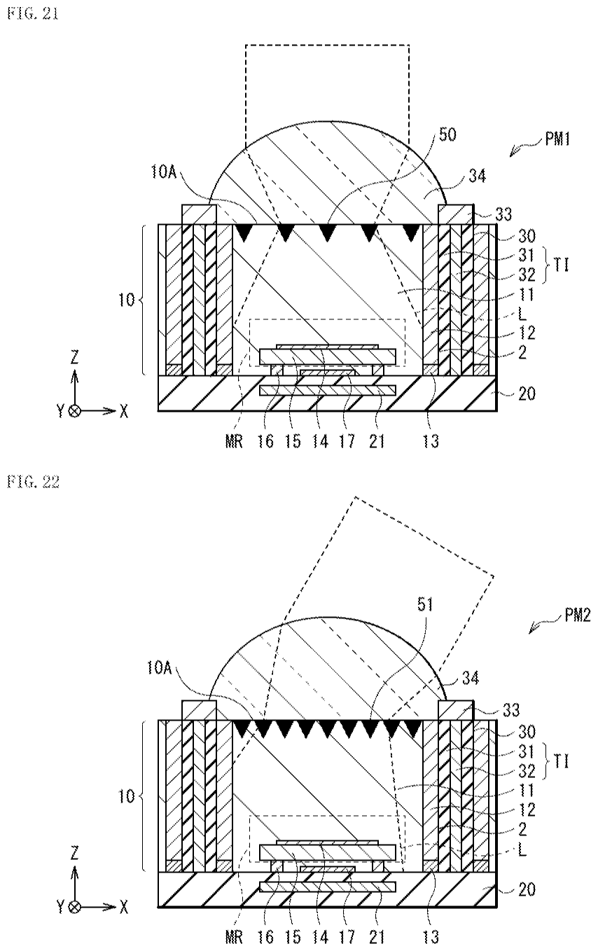

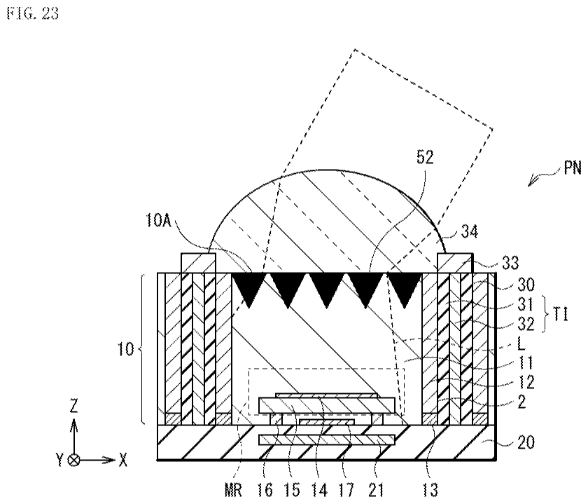

Modification Example M: An example in which an uneven shape is provided that diffuses light entering a light incident surface of an SPAD and a size of the uneven shape is changed stepwise from a middle pixel toward an outer peripheral pixel of a pixel array . . . FIGS. 21 to 22

Modification Example N: An example in which the number of an uneven shape is changed stepwise from a middle pixel toward an outer peripheral pixel of a pixel array . . . FIG. 23

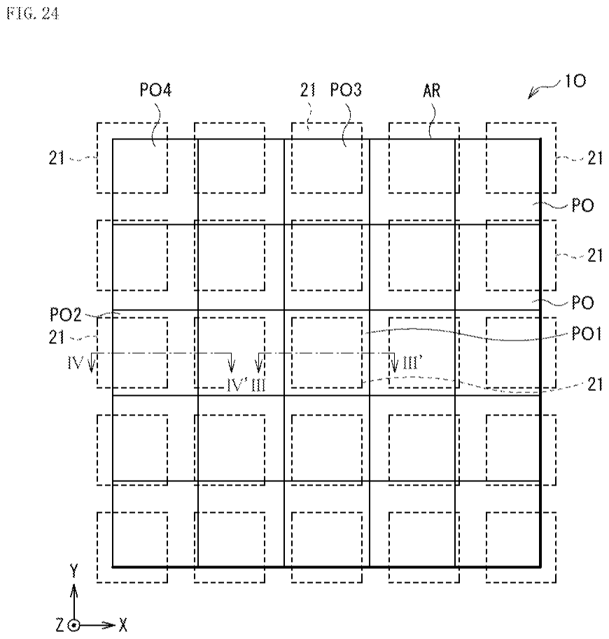

Modification Example O: An example in which a position of a light reflective film is changed stepwise from a middle pixel toward an outer peripheral pixel of a pixel array . . . FIGS. 24 to 26

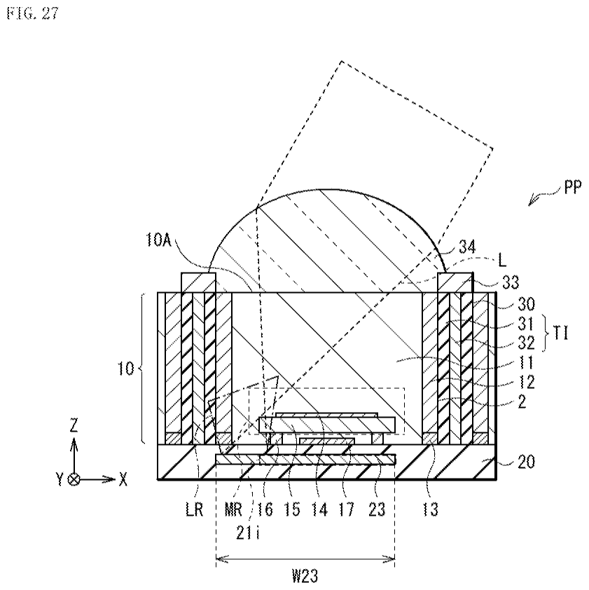

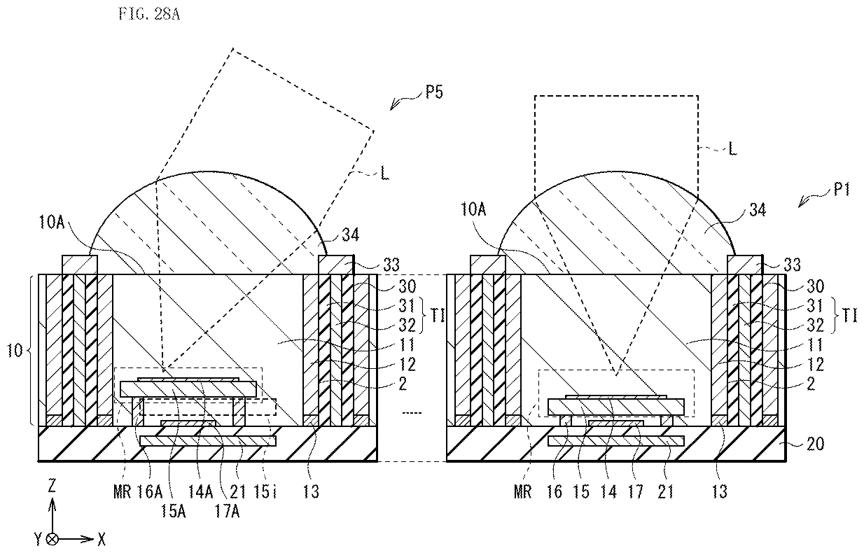

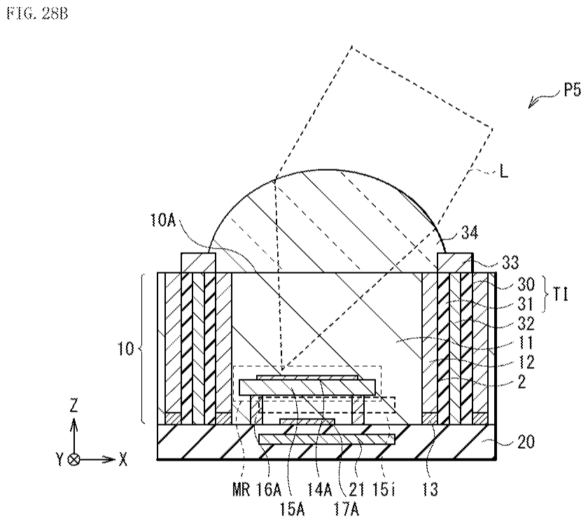

Modification Example P: An example in which a width of a light reflective film in a direction parallel to a light incident surface is changed stepwise from a middle pixel toward an outer peripheral pixel of a pixel array . . . FIG. 27

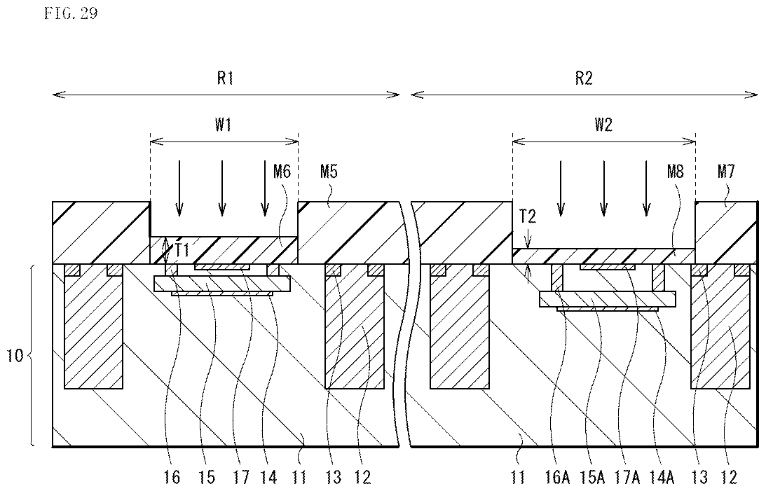

### 3. Second Embodiment . . . FIGS. 28A to 29

An example in which a pixel array including a plurality of SPADs is provided and a position of a multiplication region inside the SPAD is changed stepwise from a middle pixel toward an outer peripheral pixel of the pixel array

### 4. Modification Examples of Second Embodiment

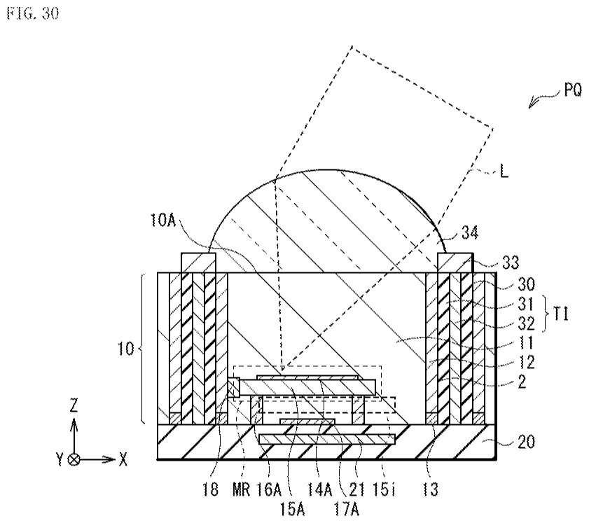

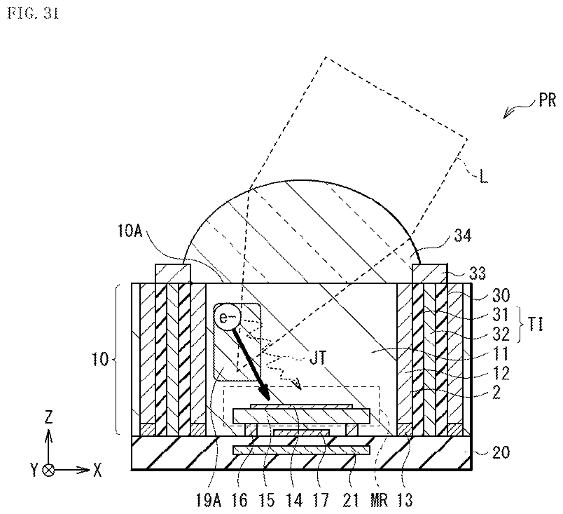

Modification Example Q: An example in which an electric field relaxation layer is provided . . . FIG. 30

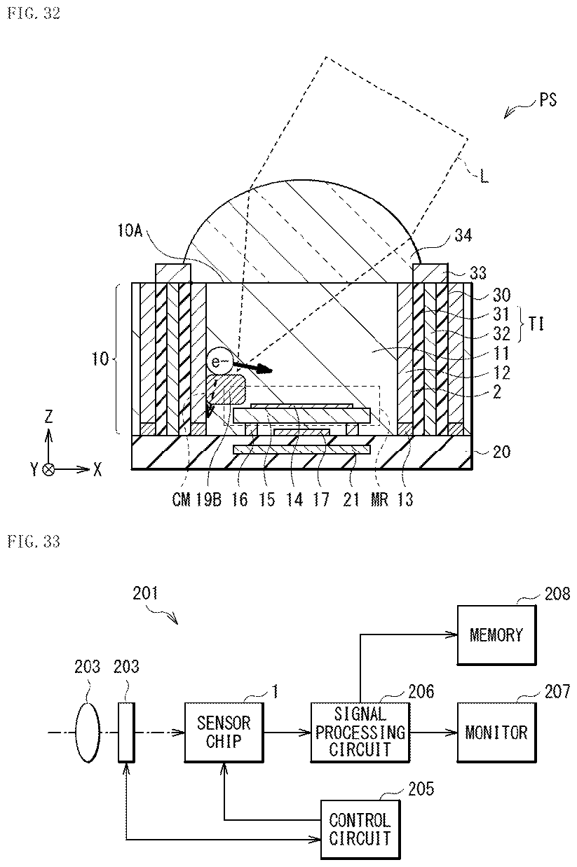

Modification Example R: An example in which an electric field adjusting impurity region is provided . . . FIG. 31

Modification Example S: An example in which a charge inducing impurity region is provided . . . FIG. 32

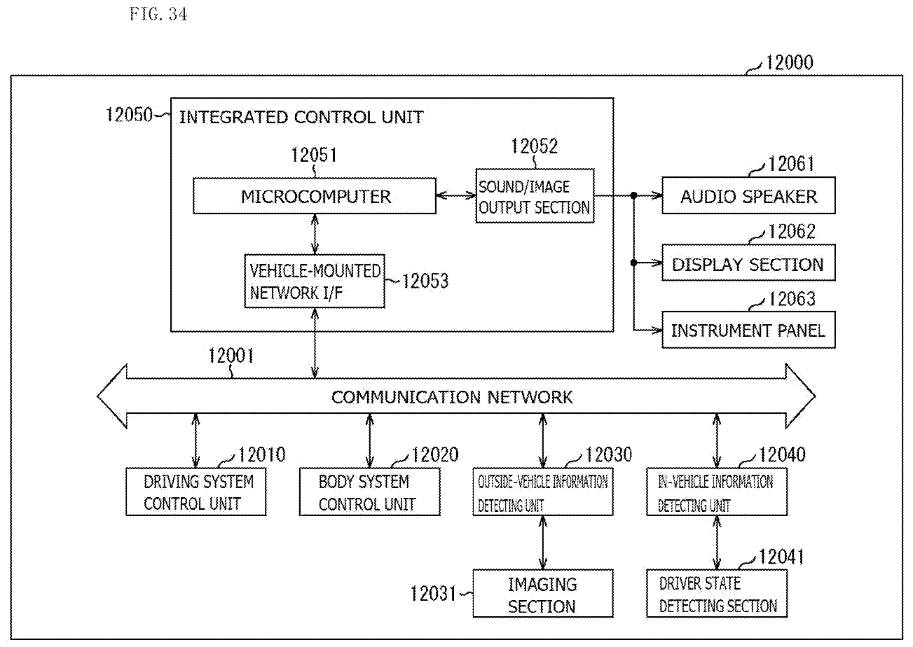

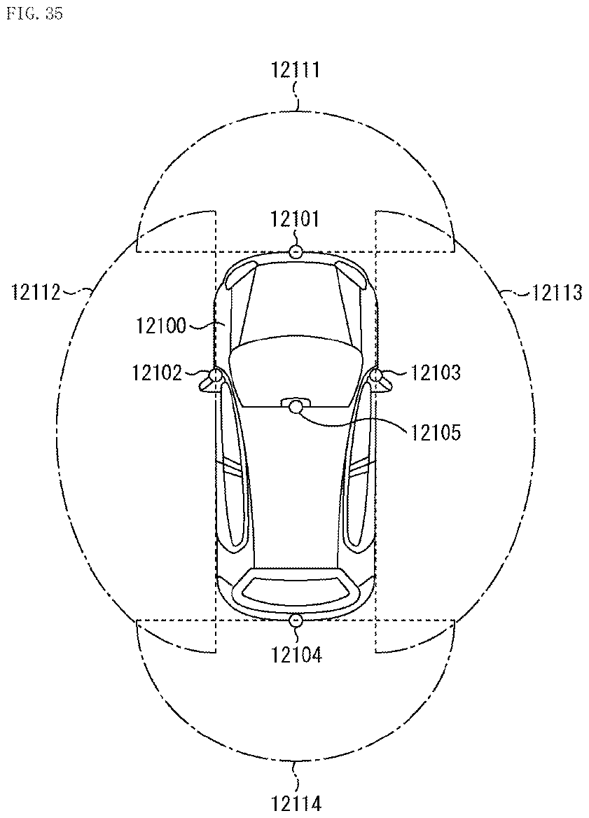

5. Application Example: An example in which a sensor chip according to any of the foregoing embodiments and modification examples thereof is applied to an electronic apparatus . . . FIG. 33
6. Practical Application Example: An example in which a sensor chip according to any of the foregoing embodiments and modification examples thereof is applied to a mobile body . . . FIGS. 34 and 35

### 7. Other Modification Examples

### 1. First Embodiment

### [Configuration Example of Sensor Chip 1]

FIG. 1 illustrates an example of a planar configuration of a sensor chip 1 according to a first embodiment of the present disclosure. The sensor chip 1 includes a pixel array AR in which a plurality of pixels P are arranged in array. The pixel P corresponds to a specific example of a “pixel” of the present disclosure. The pixel array AR corresponds to a specific example of a “pixel array” of the present disclosure.

Each pixel P has a structure in which an SPAD 2 and an on-chip lens 34 are stacked. The SPAD 2 corresponds to a specific example of a “photoelectric conversion section” of the present disclosure, and the on-chip lens 34 corresponds to a specific example of a “light-condensing section” of the present disclosure. The sensor chip 1 of the present embodiment has a configuration in which the structure of each pixel P is changed stepwise from a middle part 3 to an outer peripheral part 4 of the pixel array AR in which the plurality of pixels P are arranged in array. Specifically, in a plan view, the sensor chip 1 has a configuration in which the position of the on-chip lens 34 relative to the SPAD 2 is changed stepwise from the middle part 3 toward the outer peripheral part 4 of the pixel array AR. Hereinafter, description is given, as an example, of the sensor chip 1 of the present embodiment by referring to a pixel (a middle pixel P1) disposed in the middle part 3 of the pixel array AR and a pixel (an outer peripheral pixel P2) disposed in the outer peripheral part 4 of the pixel array AR.

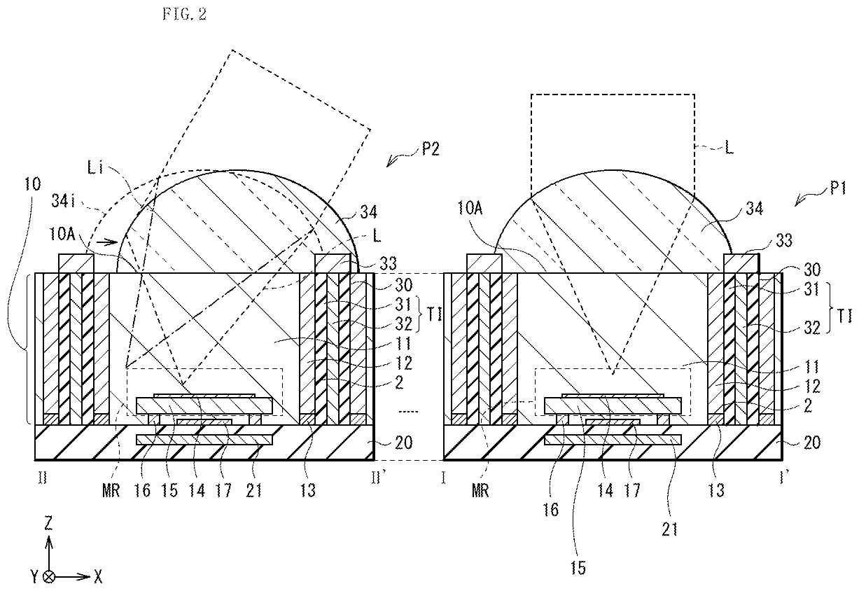

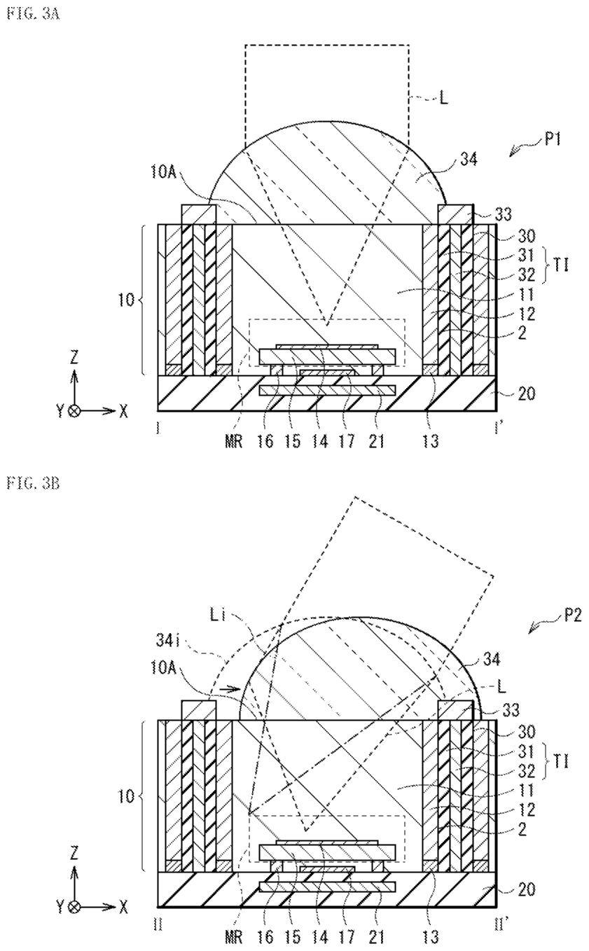

FIG. 2 illustrates an example of a cross-sectional configuration of the sensor chip 1 of FIG. 1 along I-I′ and II-II′. It is to be noted that illustration is given in FIG. 1 by omitting an inter-pixel light-shielding film 33 (described later), in order to indicate a layout of the pixel P and the on-chip lens 34. Although FIG. 2 illustrates the middle pixel P1 and the outer peripheral pixel P2 side by side, which are disposed at distant positions in the sensor chip 1, an intermediate pixel P is disposed between the middle pixel P1 and the outer peripheral pixel P2. FIG. 3A illustrates the middle pixel P1 of FIG. 2 in an enlarged manner, and corresponds to an example of a cross-sectional configuration of the middle pixel P1 of the sensor chip 1 of FIG. 1 along I-I′.

The middle pixel P1 includes the SPAD 2 and the on-chip lens 34. The SPAD 2 has a light incident surface 10A, and the on-chip lens 34 is provided to face the light incident surface 10A. The SPAD 2 includes a multiplication region MR that avalanche-multiplies carriers (electrons) by a high electric field region. The SPAD 2 corresponds to a specific example of the “photoelectric conversion section” of the present disclosure. The SPAD 2 is provided in a semiconductor substrate 10, and a surface on one side of the semiconductor substrate 10 corresponds to the light incident surface 10A of the SPAD 2. The light incident surface 10A is a surface obtained as a result of polishing of a back surface of the semiconductor substrate 10 as described later, and the light incident surface 10A is also referred to as a back surface of the semiconductor substrate 10. The sensor chip 1 (pixel array AR) is of a back-illuminated type that detects light incident from the back surface of the semiconductor substrate 10. In addition, a surface on the other side of the semiconductor substrate 10 is also referred to as a front surface.

A pixel separation groove 30 that separates neighboring pixels P from each other is provided in the semiconductor substrate 10. A pixel separation film TI is buried in the pixel separation groove 30. The pixel separation film TI has a stacked structure of, for example, an insulating film 31 such as silicon oxide (SiO₂), tantalum oxide (Ta₂O₅), hafnium oxide (HfO₂), and aluminum oxide (Al₂O₃), and a metal film 32 having a light-shielding property such as tungsten (W) and aluminum (Al). This allows the neighboring pixels P to be electrically and optically separated from each other.

Description is given of the SPAD 2 provided in the semiconductor substrate 10. A well layer 11 is provided in a region of the semiconductor substrate 10 separated by the pixel separation film TI. A p-type semiconductor region 14 on side of the light incident surface 10A and an n-type semiconductor region 15 on side of the front surface of the semiconductor substrate 10 are provided inside the well layer 11 to constitute a p-n junction. A cathode 16 is provided to penetrate from the n-type semiconductor region 15 to the side of the front surface of the semiconductor substrate 10. A p-type semiconductor region 17 is provided on the front surface of the semiconductor substrate 10. In addition, a pinning layer 12, which is the p-type semiconductor region, is provided between a side surface of the well layer 11 and the pixel separation film TI. An anode 13, which is the p-type semiconductor region, is provided at an end part of the pinning layer 12 on the side of the front surface of the semiconductor substrate 10.

The semiconductor substrate 10 is formed by silicon (Si), for example. The well layer 11 may be an n-type semiconductor region, or may be a p-type semiconductor region. The well layer 11 is preferably an n-type or p-type semiconductor region having a low concentration of, for example, about 1×10¹⁴ atoms/cm⁻³ or less. This makes it easier for the well layer 11 to be depleted, thus making it possible to improve a PDE (Photon Detection Efficiency) of the SPAD 2.

The p-type semiconductor region 14 is a high-impurity-concentration p-type semiconductor region (p+). The n-type semiconductor region 15 is a high-impurity-concentration n-type semiconductor region (n+).

The cathode 16 is a high-impurity-concentration n-type semiconductor region (n++). The cathode 16 is coupled to the n-type semiconductor region 15, and is provided to be able to apply a predetermined bias to the n-type semiconductor region 15. The p-type semiconductor region 17 is a p-type semiconductor region (p). Pinning by the p-type semiconductor region 17 is able to suppress a dark current to be generated here.

The pinning layer 12 is a p-type semiconductor region (p). The pinning layer 12 is formed to surround the side surface of the well layer 11 along the pixel separation film TI. The pinning layer 12 accumulates holes. The anode 13 is coupled to the pinning layer 12, and bias adjustment is possible from the anode 13. This intensifies hole concentration of the pinning layer 12, and the resulting stronger pinning makes it possible to suppress the generation of the dark current generated at an interface between the pixel separation film TI and the well layer 11, for example. The pinning layer 12 may have, for example, a structure in which the p-type semiconductor region (p+) and the p-type semiconductor region (p) are stacked in order, as viewed from the pixel separation film TI.

The anode 13 is a high-impurity-concentration p-type semiconductor region (p++). The anode 13 is coupled to the pinning layer 12, and is provided to be able to apply a predetermined bias to the pinning layer 12.

The above-described SPAD 2 has a configuration in which a large negative voltage applied to the anode 13, the pinning layer 12, and the p-type semiconductor region 14 causes a depletion layer to be spread from the p-n junction between the p-type semiconductor region 14 and the n-type semiconductor region 15 to form a high electric field region. When the high electric field region is formed, the multiplication region MR is formed that is able to avalanche-multiply carriers. The avalanche-multiplication generated in the multiplication region MR enables the SPAD 2 to multiply and detect carriers generated by a single photon incident from the light incident surface 10A. The SPAD 2 is configured as described above.

A wiring layer 20 in which a metal wiring line is buried in an insulating film is provided on the front surface of the semiconductor substrate 10 (a surface on side opposite to the light incident surface 10A). The wiring line inside the wiring layer 20 is configured to be coupled to each of the anode 13 and the cathode 16, for example, to be able to apply a predetermined bias thereto. In addition, a light reflective film 21 is buried in the wiring layer 20 by a metal film constituting the wiring line. The light reflective film 21 is configured to cause light having passed through the SPAD 2 to reach the side of the front surface of the semiconductor substrate 10 to be reflected back to the SPAD 2.

The inter-pixel light-shielding film 33 in contact with the pixel separation film TI is provided on the back surface of the semiconductor substrate 10. The inter-pixel light-shielding film 33 is formed by, for example, a metal having a light-shielding property such as W or Al. The inter-pixel light-shielding film 33 is configured to prevent light having obliquely entered the light incident surface 10A from entering a neighboring pixel P instead of entering a pixel P that the light should enter.

The on-chip lens 34 is provided on the back surface of the semiconductor substrate 10 to cover the light incident surface 10A. The on-chip lens 34 is formed by, for example, a light-transmissive material such as a thermoplastic positive-type photosensitive resin or silicon nitride. The on-chip lens 34 is configured to condense incident light L entering the light incident surface 10A to the multiplication region MR.

FIG. 3B is an enlarged view of the outer peripheral pixel P2 of FIG. 2, and corresponds to an example of a cross-sectional configuration of the outer peripheral pixel P2 of the sensor chip 1 of FIG. 1 along II-II′. The outer peripheral pixel P2 is a pixel P positioned at an end part of the pixel array AR in a −X direction as viewed from the middle pixel P1.

The outer peripheral pixel P2 includes the SPAD 2 provided in the semiconductor substrate 10, the wiring layer 20 formed on the front surface of the semiconductor substrate 10, the inter-pixel light-shielding film 33 provided on the back surface of the semiconductor substrate, and the on-chip lens 34. The outer peripheral pixel P2 has the same structures as those of the middle pixel P1 for the inner structure of the semiconductor substrate 10 including the SPAD 2, the wiring layer 20, and the inter-pixel light-shielding film 33, and thus the descriptions thereof are omitted.

FIG. 3B illustrates, by a dotted line 34i, a position of the on-chip lens 34 relative to the SPAD 2 in the middle pixel P1. In the outer peripheral pixel P2 positioned in the −X direction as viewed from the middle pixel P1, the on-chip lens 34 is provided at a position shifted in an X direction from the dotted line 34i. The on-chip lens 34 shifted in the X direction is provided to partially protrude toward the neighboring pixel P.

In the sensor chip 1, the structure of the light-condensing section that condenses light to the SPAD 2 is changed stepwise from the middle pixel P1 toward the outer peripheral pixel P2 of the pixel array AR. Specifically, the position of the on-chip lens 34 is changed stepwise from the middle pixel P1 toward the outer peripheral pixel P2. As illustrated in FIG. 1, in an outer peripheral pixel P3 positioned in a Y direction as viewed from the middle pixel P1, the on-chip lens 34 is provided at a position shifted in a −Y direction. In an outer peripheral pixel P4 at a corner part of the pixel array AR positioned in (−X, Y) directions as viewed from the middle pixel P1, the on-chip lens 34 is provided at a position shifted in (X, −Y) directions. Also in the intermediate pixel P positioned between the middle pixel P1 and the outer peripheral pixel P2, P3, or P4, the position of the on-chip lens 34 is shifted similarly. The shifting direction of the on-chip lens 34 in each pixel P is a direction of the middle pixel P1 as viewed from any pixel P. A magnitude (distance) by which the on-chip lens 34 is shifted is thereafter also referred to as a shift width. The shift width of the on-chip lens 34 in each pixel P is set depending on a distance from the middle pixel P1 of each pixel P; the shift width is set larger as being farther from the middle pixel P1, and is set smaller as being closer thereto. In this manner, in the sensor chip 1, the position of the on-chip lens 34 is changed stepwise from the middle pixel P1 toward the outer peripheral pixel P2, P3, or P4.

### [Manufacturing Method of Sensor Chip 1]

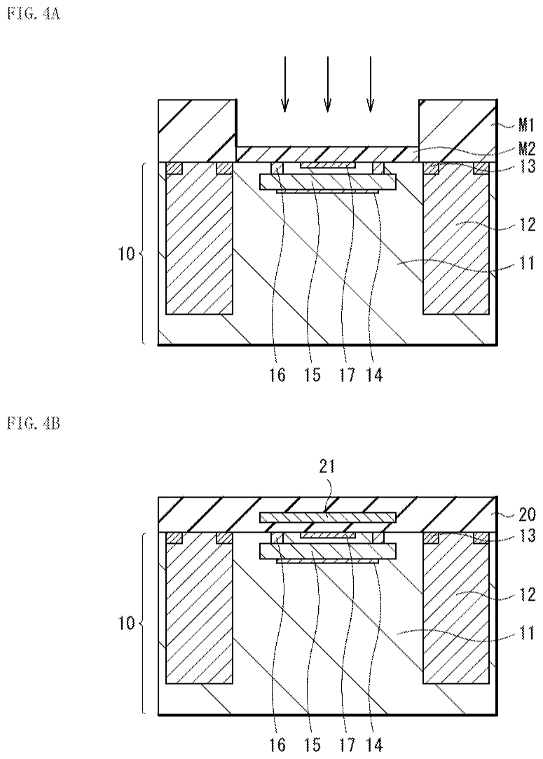

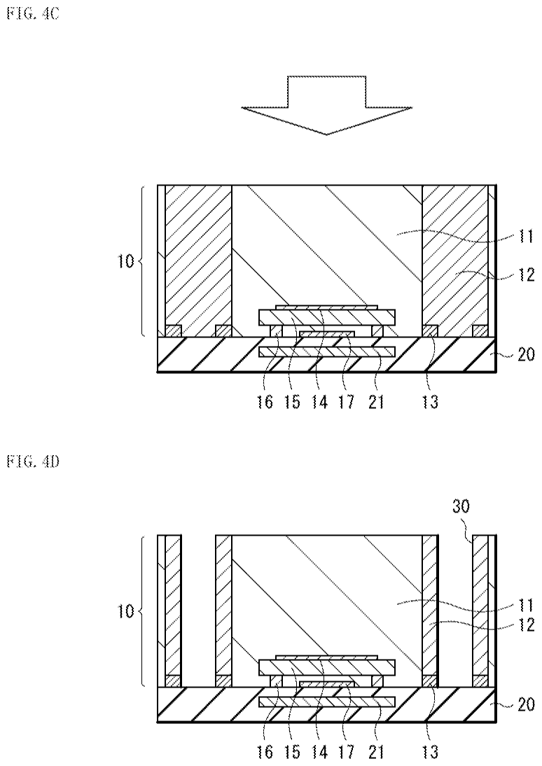

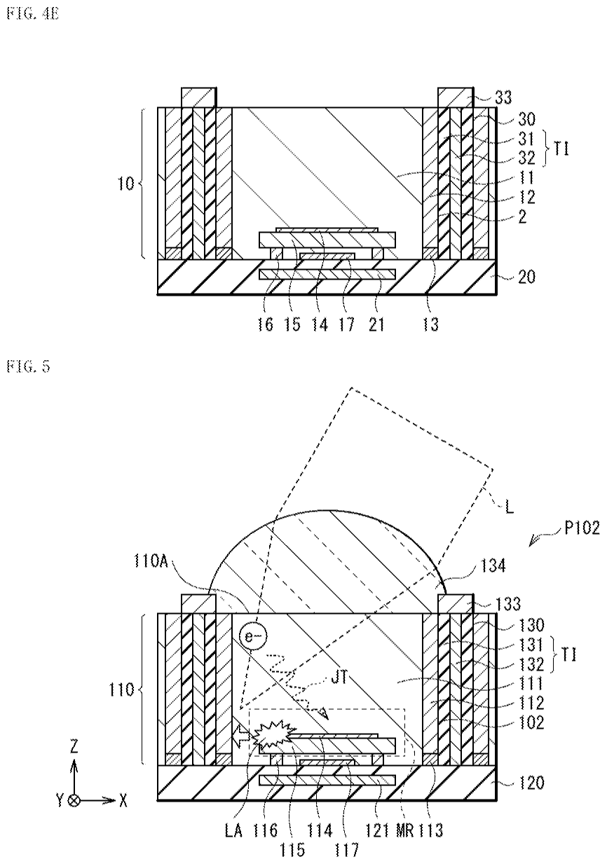

Next, description is given of a manufacturing method of the sensor chip 1. FIGS. 4A to 4E illustrate an example of manufacturing processes of the sensor chip 1. The middle pixel P1 and the outer peripheral pixel P2 are able to be manufactured similarly, except for a step of forming the on-chip lens 34; description is given here of a manufacturing process of the outer peripheral pixel P2.

First, a resist mask M1 having an opening at a position corresponding to an ion injection region and a resist mask M2 that covers a position corresponding to the ion injection region are formed on the front surface of the semiconductor substrate 10, and thereafter n-type impurities or p-type impurities are injected at a predetermined ion injection energy. As illustrated in FIG. 4A, this allows for respective formations of the well layer 11, the pinning layer 12, the anode 13, the p-type semiconductor region 14, the n-type semiconductor region 15, the cathode 16, and the p-type semiconductor region 17. For example, a magnitude of the ion injection energy and a thickness of the resist mask M2 enable a depth of ion injection to be controlled. After the ion injection, the resist masks M1 and M2 are removed.

Next, for example, formation of an insulating film by a CVD (Chemical Vapor Deposition) method, formation of a metal film by a sputtering method, and etching working of the metal film are repeated, to thereby form, on the front surface of the semiconductor substrate 10, the wiring layer 20 in which a wiring line is buried in the insulating film, as illustrated in FIG. 4B. At this time, the light reflective film 21 is formed by the metal film constituting the wiring line.

Subsequently, as illustrated in FIG. 4C, the semiconductor substrate 10 is polished by, for example, a CMP (Chemical Mechanical Polishing) method from the back surface (surface on side opposite to a formation surface of the wiring layer 20) until the pinning layer 12 is exposed. FIG. 4C is illustrated in a manner vertically inverted relative to FIG. 4B.

Next, a resist pattern having an opening at a position corresponding to a pixel separation region is formed, and thereafter etching processing such as reactive ion etching (RIE: Reactive Ion Etching) is conducted to thereby form the pixel separation groove 30 as illustrated in FIG. 4D. The pixel separation groove 30 is formed, for example, to penetrate the semiconductor substrate 10. After the etching processing, the resist pattern is removed.

Subsequently, the insulating film 31 and the metal film 32 are stacked to be embedded in the pixel separation groove 30 by the CVD method or an ALD (Atomic Layer Deposition) method, for example, to form the pixel separation film TI. Next, a metal film is formed by a sputtering method, for example, and a resist pattern having an opening at a position corresponding to the light incident surface 10A is formed. Thereafter, etching processing such as the RIE is conducted to thereby form the inter-pixel light-shielding film 33 as illustrated in FIG. 4E. After the etching processing, the resist pattern is removed. Subsequently, the on-chip lens 34 is formed to cover the light incident surface 10A. The formation of the on-chip lens 34 is performed, for example, by film formation of a thermoplastic positive-type photosensitive resin and reflow processing. Here, a formation position of the on-chip lens 34 is set to a position shifted in the X direction from immediately above the light incident surface 10A. In this manner, the outer peripheral pixel P2 is formed. It is to be noted that setting the formation position of the on-chip lens 34 immediately above the light incident surface 10A makes it possible to form the middle pixel P1. In this manner, the sensor chip 1 is manufactured.

### [Operation of Sensor Chip 1]

In the sensor chip 1, application of a large negative voltage to the anode 13, the pinning layer 12, and the p-type semiconductor region 14 in the SPAD 2 of each pixel P causes a depletion layer to be spread from the p-n junction between the p-type semiconductor region 14 and the n-type semiconductor region 15 to form a high electric field region. The resulting high electric field region allows for formation of the multiplication region MR that is able to avalanche-multiply carriers. The multiplication region MR multiplies carriers generated by a single photon incident from the light incident surface 10A to generate multiplied signal charges. The resulting signal charges are taken out of the SPAD 2, and are subjected to signal processing by a signal processing circuit.

The sensor chip 1 is able to be used as a distance measurement sensor according to a ToF (Time of Flight) method. In the ToF method, signal delay time between a signal by signal charges and a reference signal is converted to a distance to a measurement target. The signal processing circuit calculates the signal delay time, for example, from the reference signal and the signal by the signal charges obtained from the SPAD 2 of each pixel P. The resulting signal delay time is converted to a distance, thereby allowing for measurement of a distance to the measurement target.

### [Workings and Effects of Sensor Chip 1]

The sensor chip 1 of the first embodiment includes the pixel array AR in which the plurality of pixels P are arranged in array. Each pixel P includes the SPAD 2, and the on-chip lens 34 provided to face the light incident surface 10A of the SPAD 2. Here, the plurality of pixels P are subjected to pupil correction. The pupil correction is described below.

In the middle pixel P1, more light enters the light incident surface 10A substantially perpendicularly as illustrated in FIG. 3A. The incident light L having entered the light incident surface 10A substantially perpendicularly is condensed to the multiplication region MR by the on-chip lens 34. In the multiplication region MR, carriers generated by a single photon are avalanche-multiplied. The incident light L is condensed to the multiplication region MR by the on-chip lens 34 to thereby enhance the PDE.

In the outer peripheral pixel P2, more light enters the light incident surface 10A in an oblique direction as illustrated in FIG. 3B. The oblique direction in which the incident light L enters refers to a direction inclined to the −X direction from a direction perpendicular to the light incident surface 10A (−Z direction).

Description is given here of an outer peripheral pixel P102 of a sensor chip 101 according to a reference embodiment to describe the workings and effects of the sensor chip 1. FIG. 5 illustrates a cross-sectional configuration of the outer peripheral pixel P102 of the sensor chip P101 of the reference embodiment; similarly to the middle pixel P1 illustrated in FIG. 3A, an inter-pixel light-shielding film 133 is provided, in contact with the pixel separation film TI, on a light incident surface 110A of a semiconductor substrate 110. In addition, an on-chip lens 134 is provided immediately above the light incident surface 110A to cover the light incident surface 110A. In the outer peripheral pixel P102, a pixel separation groove 130 is provided in a semiconductor substrate 100, and the pixel separation film TI in which an insulating film 131 and a metal film 132 are stacked is buried in the pixel separation groove 130. The semiconductor substrate 110 separated by the pixel separation groove 130 is provided with a well layer 111, a pinning layer 112, an anode 113, a p-type semiconductor region 114, an n-type semiconductor region 115, a cathode 116, and a p-type semiconductor region 117, and an SPAD 102 is configured. One surface (back surface) of the semiconductor substrate 110 serves as the light incident surface 110A of the SPAD 102. A wiring layer 120 in which a wiring line is buried in an insulating film is provided on the other surface (front surface) of the semiconductor substrate 110, and a light reflective film 121 is provided in the wiring layer 120 by a metal film constituting the wiring line.

As illustrated in FIG. 5, more incident light L obliquely enters the light incident surface 110A in the outer peripheral pixel P102 of the pixel array. A photoelectric conversion region to which such obliquely incident light L is condensed is deviated in the −X direction in the SPAD 102, and is positioned distant from the multiplication region MR. This results in lowered PDE in the outer peripheral pixel P102. Even when carriers are generated, it is difficult for the carriers to reach the multiplication region MR, because of being distant from the multiplication region MR, which also constitutes a factor of the lowered PDE.

In addition, when the incident light L obliquely enters the light incident surface 110A to generate carriers at a position distant from the multiplication region MR, the mobility of the carriers is low because workings by a high electric field is not enough at the position distant from the multiplication region MR, and thus the carriers travel a longer distance than the shortest path to the multiplication region MR as indicated by a dotted line JT. For this reason, it takes time for the carriers to reach the multiplication region MR, and thus jitter is deteriorated.

In addition, the incident light L obliquely enters the light incident surface 110A, thus causing avalanche-multiplication to be often generated at an end part of the outer peripheral pixel P102. Light LA is generated during the avalanche-multiplication; the light LA generated at the end part of the outer peripheral pixel P102 results in reaching a neighboring pixel prior to attenuation. As a result, crosstalk is deteriorated.

As illustrated in FIG. 3B, the on-chip lens 34 is shifted in the X direction in the outer peripheral pixel P2 of the sensor chip 1. This causes an optical path of the incident light L to be corrected to allow the incident light obliquely entering the light incident surface 10A to be close to the multiplication region MR. It is to be noted that, in FIG. 3B, the dotted line 34i indicates a position corresponding to the position of the on-chip lens 34 of the outer peripheral pixel P102 of the sensor chip 101 of the reference embodiment illustrated in FIG. 5. In addition, in FIG. 3B, an alternate long and short dash line Li indicates a position corresponding to the optical path at the time when the incident light obliquely enters in the outer peripheral pixel P102 of the sensor chip 101 of the reference embodiment illustrated in FIG. 5. Shifting the position of the on-chip lens 34 in the X direction in the outer peripheral pixel P2 makes it possible to correct the optical path of the incident light L to allow the incident light obliquely entering the light incident surface 10A to be close to the multiplication region MR.

In the outer peripheral pixel P2 of the sensor chip 1 described above, the optical path of the incident light L is corrected to allow the incident light obliquely entering the light incident surface 10A to be close to the multiplication region MR, thus enabling the photoelectric conversion region to be close to the multiplication region MR, making it possible to improve the PDE. In addition, it is possible to cause the position where carriers are generated to be close to the multiplication region MR, thus making it possible to suppress the jitter. In addition, it is possible to cause the position where the avalanche-multiplication is generated to be away from an end part of the outer peripheral pixel P2, thus making it possible to suppress the crosstalk.

In the sensor chip 1, for example, the shift width of the position of the on-chip lens 34 of each pixel P is provided to be changed stepwise from the middle pixel P1 toward the outer peripheral pixel P2. For example, the shift width is set depending on the distance from the middle pixel P1 of each pixel P; the shift width is set larger as being farther from the middle pixel P1, and is set smaller as being closer thereto. One reason for this is that less light obliquely enters the light incident surface 10A in the middle, whereas more light obliquely enters on the outer periphery, with an angle being also larger as inclined obliquely. In this manner, changing the shift width of the position of the on-chip lens 34 stepwise depending on the position in the pixel array AR makes it possible to correct the optical path of the incident light L depending on the position in the pixel array AR and to suppress inequality of the characteristics among the pixels P, thus making it possible to achieve pupil correction of the sensor chip 1.

It is to be noted that the “light-condensing section” of the present disclosure means a member that changes the optical path of the incident light L to cause the incident light L to be close to the multiplication region MR, but also includes, in addition thereto, a member that that blocks a portion of the incident light L not to enter a region distant from the multiplication region MR, and a member that increases the chance of the incident light L passing through the multiplication region MR. Specifically, the “light-condensing section” corresponds to the inter-pixel light-shielding film 33, an inner lens 36, an uneven shape 50 of the light incident surface 10A, and the light reflective film 21, in addition to the on-chip lens 34, as illustrated in the following modification examples.

As described hereinabove, it is possible to improve the PDE in the outer peripheral pixel, in the sensor chip 1 of the first embodiment. In addition, it is possible to suppress the jitter and the crosstalk, thereby making it possible to equalize the characteristics of the middle pixel and the outer peripheral pixel of the pixel array.

### 2. Modification Examples of First Embodiment

Hereinafter, description is given of modification examples of the sensor chip 1 according to the foregoing first embodiment. It is to be noted that, in the following modification examples, components common to those of the foregoing first embodiment are denoted with the same reference numerals.

### Modification Example A

The above-described sensor chip 1 has a configuration in which the on-chip lens 34 is shifted stepwise in the X direction from the middle part 3 toward the outer peripheral part 4, and is thereby provided to partially protrude toward the neighboring pixel P. However, the present disclosure is not limited thereto, and there may also be a configuration in which the on-chip lens 34 is partially removed not to protrude toward the neighboring pixel P.

FIG. 6 illustrates an example of a cross-sectional configuration of an outer peripheral pixel PA of a sensor chip 1A as Modification Example A. The on-chip lens 34 is provided with a cutout part 35 as a result of removal of a protruding portion toward the pixel P neighboring in the X direction. The cutout part 35 is positioned on the inter-pixel light-shielding film 33. Except for those described above, the sensor chip 1A has configurations similar to those of the sensor chip 1.

Similarly to the sensor chip 1, it is possible to improve the PDE in the outer peripheral pixel PA of the sensor chip 1A. In addition, it is possible to suppress the jitter and the crosstalk, thereby making it possible to equalize the characteristics of the middle pixel and the outer peripheral pixel of the pixel array. Further, it is possible to suppress an influence on a neighboring pixel as a result of protrusion of the on-chip lens 34 toward the neighboring pixel.

### Modification Example B

The above-described sensor chip 1 has a configuration in which the on-chip lens 34 is shifted stepwise in the X direction from the middle part 3 toward the outer peripheral part 4, and is thereby provided to partially protrude toward the neighboring pixel P. However, the present disclosure is not limited thereto, and there may also be a configuration in which a width W34 of the on-chip lens 34 in a direction parallel to the light incident surface 10A is decreased stepwise not to protrude toward the neighboring pixel P.

FIG. 7 illustrates an example of a cross-sectional configuration of an outer peripheral pixel PB of a sensor chip 1B as Modification Example B. The on-chip lens 34 is provided to be shifted in the X direction and not to protrude toward the neighboring pixels P as a result of decreased width W34 in the direction parallel to the light incident surface 10A. Except for those described above, the sensor chip 1B has configurations similar to those of the sensor chip 1.

Similarly to the sensor chip 1, it is possible to improve the PDE in the outer peripheral pixel PB of the sensor chip 1B. In addition, it is possible to suppress the jitter and the crosstalk, thereby making it possible to equalize the characteristics of the middle pixel and the outer peripheral pixel of the pixel array. Further, it is possible to suppress an influence on a neighboring pixel as a result of protrusion of the on-chip lens toward the neighboring pixel.

### Modification Example C

In the above-described sensor chip 1, the example is given in which the pixel separation film TI penetrates the semiconductor substrate 10, but this is not limitative. For example, there may also be a configuration in which the inter-pixel light-shielding film 33 is not provided and the pixel separation film TI is not formed at a predetermined depth from the light incident surface 10A of the semiconductor substrate 10.

FIG. 8 illustrates an example of a cross-sectional configuration of an outer peripheral pixel PC of a sensor chip 1C as Modification Example C. The on-chip lens 34 is shifted in the X direction. The inter-pixel light-shielding film 33 is not provided. In addition, the pixel separation groove 30 is formed to a halfway depth of the semiconductor substrate 10 from the front surface of the semiconductor substrate 10 (surface on side opposite to the light incident surface 10A), and the pixel separation film TI is formed to be buried in the pixel separation groove 30. In this manner, the sensor chip 1C has a configuration in which the pixel separation film TI is not provided at a predetermined depth 30A from the back surface (light incident surface 10A) of the semiconductor substrate 10. Except for those described above, the sensor chip 1C has configurations similar to those of the sensor chip 1.

Description is given here of the outer peripheral pixel P2 of the sensor chip 1 to describe workings and effects of the sensor chip 1C. FIG. 9 illustrates a cross-sectional configuration of the outer peripheral pixel P2 of the sensor chip 1. Although being similar to the cross-sectional configuration illustrated in FIG. 3B, FIG. 9 differs therefrom in that a portion of the incident light L is blocked by the inter-pixel light-shielding film 33, and a shadow region RS is constituted. The shadow region RS may be generated depending on a magnitude of the shift width of the on-chip lens 34 and an inclination of the incident light L. When the shadow region RS is generated, the PDE results in being lowered, as a matter of course.

In the outer peripheral pixel PC of the sensor chip 1C illustrated in FIG. 8, the inter-pixel light-shielding film 33 is not provided. In addition, the pixel separation film TI is not provided at a predetermined depth from the light incident surface 10A. This allows for a configuration in which the incident light L is not blocked by the inter-pixel light-shielding film 33 and in the vicinity of an end part of the pixel separation film TI on the side of the light incident surface 10A, thus making it difficult for the shadow region RS to be formed.

Similarly to the sensor chip 1, it is possible to improve the PDE in the outer peripheral pixel PC of the sensor chip 1C. In addition, it is possible to suppress the jitter and the crosstalk, thereby making it possible to equalize the characteristics of the middle pixel and the outer peripheral pixel of the pixel array. Further, the formation of the shadow region as a result of blocking of the incident light is suppressed, and the lowering in the PDE is suppressed.

### Modification Example D

The above-described sensor chip 1C has a configuration in which the inter-pixel light-shielding film 33 is not provided, and in addition the pixel separation film TI is not provided at a predetermined depth from the light incident surface 10A; however, the present disclosure is not limited thereto. For example, there may be a configuration in which a second pixel separation film TI2 having a predetermined depth from the light incident surface 10A is provided, and an inter-pixel light-shielding film 44 is provided in contact with the second pixel separation film TI2.

FIG. 10 illustrates an example of a cross-sectional configuration of an outer peripheral pixel PD of a sensor chip 1D as Modification Example D. The on-chip lens 34 is shifted in the X direction. The pixel separation film TI is not provided at a predetermined depth from the light incident surface 10A. The inter-pixel light-shielding film 33 in contact with the pixel separation film TI is not formed. In addition, the second pixel separation film TI2 having a predetermined depth from the light incident surface 10A is provided at a position spaced from the pixel separation film TI in the X direction. The inter-pixel light-shielding film 44 is provided in contact with the second pixel separation film TI2. Except for those described above, the sensor chip 1D has configurations similar to those of the sensor chip 1.

Next, description is given of a manufacturing method of sensor chip 1D. FIGS. 11A to 11F each illustrate an example of a manufacturing process of the outer peripheral pixel PD of the sensor chip 1D. The middle pixel and the outer peripheral pixel PD are able to be manufactured similarly, except for steps of forming the pixel separation film TI and the second pixel separation film Ti2; description is given here of a manufacturing process of the outer peripheral pixel PD.

First, a resist mask M3 having an opening at a position corresponding to an ion injection region and a resist mask M4 that covers a position corresponding to the ion injection region are formed on the front surface of the semiconductor substrate 10, and thereafter n-type impurities or p-type impurities are injected at a predetermined ion injection energy, to allow for respective formations of the well layer 11, the pinning layer 12, the anode 13, the p-type semiconductor region 14, the n-type semiconductor region 15, the cathode 16, the p-type semiconductor region 17, and a p-type semiconductor region 40, as illustrated in FIG. 11A. After the ion injection, the resist masks M3 and M4 are removed.

Next, a resist pattern having an opening at a position corresponding to a pixel separation region is formed, and thereafter etching processing such as the RIE is conducted to thereby form the pixel separation groove 30 as illustrated in FIG. 11B. The pixel separation groove 30 is formed, for example, to have a halfway depth of the semiconductor substrate 10 from the front surface of the semiconductor substrate 10. A front surface of the pinning layer 12 is exposed to a bottom surface and a side surface inside the pixel separation groove 30. After the etching processing, the resist pattern is removed.

Subsequently, the insulating film 31 and the metal film 32 are stacked to be embedded in the pixel separation groove 30 by the CVD method or the ALD method, for example, to form the pixel separation film TI. Next, for example, formation of an insulating film by the CVD method, formation of a metal film by a sputtering method, and etching working of the metal film are repeated, to thereby form, on the front surface of the semiconductor substrate 10, the wiring layer 20 in which a wiring line is buried in the insulating film, as illustrated in FIG. 11C. At this time, the light reflective film 21 is formed by the metal film constituting the wiring line.

Subsequently, as illustrated in FIG. 11D, the semiconductor substrate 10 is polished by, for example, the CMP method from the back surface (surface on side opposite to a formation surface of the wiring layer 20) until the p-type semiconductor region 40 is exposed. FIG. 11D is illustrated in a manner vertically inverted relative to FIG. 11C.

Next, a resist pattern having an opening at a position corresponding to a second pixel separation region is formed, and thereafter etching processing such as the RIE is conducted to thereby form a second pixel separation groove 41 as illustrated in FIG. 11E. The second pixel separation groove 41 is formed, for example, to have a halfway depth of the semiconductor substrate 10 from the back surface of the semiconductor substrate 10. A front surface of the p-type semiconductor region 40 is exposed to a bottom surface and a side surface inside the second pixel separation groove 41. After the etching processing, the resist pattern is removed.

Subsequently, an insulating film 42 and a metal film 43 are stacked to be embedded in the second pixel separation groove 41 by the CVD method or the ALD method, for example, to form the second pixel separation film TI2. Next, a metal film is formed by a sputtering method, for example, and a resist pattern having an opening at a position corresponding to the light incident surface 10A is formed. Thereafter, etching processing such as the RIE is conducted to thereby form the inter-pixel light-shielding film 44 as illustrated in FIG. 11F. After the etching processing, the resist pattern is removed. Next, the on-chip lens 34 is formed to cover the light incident surface 10A. In this manner, the outer peripheral pixel PD is formed, and the sensor chip 1D is manufactured.

In the outer peripheral pixel PD of the sensor chip 1D illustrated in FIG. 10, the inter-pixel light-shielding film 33 is not provided, and the pixel separation film TI is not provided at a predetermined depth from the light incident surface 10A. This allows for a configuration in which the incident light L is not blocked by the inter-pixel light-shielding film 33 and in the vicinity of an end part of the pixel separation film TI on the side of the light incident surface 10A, thus making it difficult for the shadow region RS to be formed. Further, the second pixel separation film TI2 is provided, thus making it possible to prevent light leakage into a neighboring pixel inside the semiconductor substrate 10 and to achieve optical separation between pixels. Further, the inter-pixel light-shielding film 44 is provided, thus making it possible to prevent light having obliquely entered the light incident surface 10A from entering a neighboring pixel P instead of entering a pixel P that the light should enter.

Similarly to the sensor chip 1C, it is possible to improve the PDE in the outer peripheral pixel PD of the sensor chip 1D. In addition, it is possible to suppress the jitter and the crosstalk, thereby making it possible to equalize the characteristics of the middle pixel and the outer peripheral pixel of the pixel array. Further, the formation of the shadow region as a result of blocking of the incident light by the inter-pixel light-shielding film, or the like is suppressed, and the lowering in the PDE due to the shadow region is suppressed.

### Modification Example E

In the above-described sensor chip 1, sizes of the on-chip lens 34 of the middle pixel P1 and the on-chip lens 34 of the outer peripheral pixel P2 are the same, but the present disclosure is not limited thereto; the width W34 of the on-chip lens 34 in the direction parallel to the light incident surface 10A may be changed stepwise from the middle pixel P1 toward the outer peripheral pixel P2.

FIG. 12 illustrates an example of a cross-sectional configuration of an outer peripheral pixel PE of a sensor chip 1E as Modification Example E. The on-chip lens 34 of the outer peripheral pixel PE is provided to allow the width W34 in the direction parallel to the light incident surface 10A to be smaller than the on-chip lens 34 of the middle pixel. In the sensor chip 1E, the width W34 of the on-chip lens 34 in the direction parallel to the light incident surface 10A is changed stepwise from the middle pixel toward the outer peripheral pixel PE. In the outer peripheral pixel PE, the on-chip lens 34 is not shifted in the X direction. Except for those described above, the sensor chip 1E has configurations similar to those of the sensor chip 1.

In the outer peripheral pixel PE of the sensor chip 1E, the width of the on-chip lens 34 is adjusted to be small, thereby correcting an optical path of the incident light L to allow the incident light obliquely entering the light incident surface 10A to be close to the multiplication region MR, thus making it possible to improve the PDE.

Similarly to the sensor chip 1, it is possible to improve the PDE in the outer peripheral pixel PE of the sensor chip 1E. In addition, it is possible to suppress the jitter and the crosstalk, thereby making it possible to equalize the characteristics of the middle pixel and the outer peripheral pixel of the pixel array.

### Modification Example F

In the above-described sensor chip 1, curvatures of the on-chip lens 34 of the middle pixel P1 and the on-chip lens 34 of the outer peripheral pixel P2 are the same, but the present disclosure is not limited thereto; the curvature of the on-chip lens 34 may be changed stepwise from the middle pixel P1 toward the outer peripheral pixel P2.

FIG. 13 illustrates an example of a cross-sectional configuration of an outer peripheral pixel PF of a sensor chip 1F as Modification Example F. The on-chip lens 34 of the outer peripheral pixel PF is provided to allow the curvature thereof to be smaller than that of the on-chip lens 34 of the middle pixel. In the sensor chip 1F, the curvature of the on-chip lens 34 is changed stepwise from the middle pixel toward the outer peripheral pixel PF. In the outer peripheral pixel PF, the on-chip lens 34 is not shifted in the X direction. Except for those described above, the sensor chip 1F has configurations similar to those of the sensor chip 1.

In the outer peripheral pixel PF of the sensor chip 1F, the curvature of the on-chip lens 34 is adjusted to be small, thereby correcting an optical path of the incident light L to allow the incident light obliquely entering the light incident surface 10A to be close to the multiplication region MR, thus making it possible to improve the PDF.

Similarly to the sensor chip 1, it is possible to improve the PDF in the outer peripheral pixel PF of the sensor chip 1F. In addition, it is possible to suppress the jitter and the crosstalk, thereby making it possible to equalize the characteristics of the middle pixel and the outer peripheral pixel of the pixel array.

### Modification Example G

In the above-described sensor chip 1, sizes of the on-chip lens 34 of the middle pixel P1 and the on-chip lens 34 of the outer peripheral pixel P2 are the same, but the present disclosure is not limited thereto; a height H34 of the on-chip lens 34 may be changed stepwise from the middle pixel P1 toward the outer peripheral pixel P2.

FIG. 14 illustrates an example of a cross-sectional configuration of an outer peripheral pixel PG of a sensor chip 1G as Modification Example G. The on-chip lens 34 of the outer peripheral pixel PG is provided to allow the height H34 thereof to be lower than the on-chip lens 34 of the middle pixel. In the sensor chip 1G, the height H34 of the on-chip lens 34 is changed stepwise from the middle pixel toward the outer peripheral pixel PG. In the outer peripheral pixel PG, the on-chip lens 34 is not shifted in the X direction. Except for those described above, the sensor chip 1G has configurations similar to those of the sensor chip 1.

In the outer peripheral pixel PG of the sensor chip 1G, the height of the on-chip lens 34 is adjusted to be low, thereby correcting an optical path of the incident light L to allow the incident light obliquely entering the light incident surface 10A to be close to the multiplication region MR, thus making it possible to improve the PDE.

Similarly to the sensor chip 1, it is possible to improve the PDE in the outer peripheral pixel PG of the sensor chip 1G. In addition, it is possible to suppress the jitter and the crosstalk, thereby making it possible to equalize the characteristics of the middle pixel and the outer peripheral pixel of the pixel array.

### Modification Example H

In the above-described sensor chip 1, widths in the direction parallel to the light incident surface 10A of the inter-pixel light-shielding film 33 of the middle pixel P1 and the inter-pixel light-shielding film 33 of the outer peripheral pixel P2 are the same, but the present disclosure is not limited thereto; the width of the inter-pixel light-shielding film 33 may be changed stepwise from the middle pixel P1 toward the outer peripheral pixel P2. The inter-pixel light-shielding film 33 corresponds to another specific example of the “light-condensing section” of the present disclosure.

FIG. 15 illustrates an example of a cross-sectional configuration of an outer peripheral pixel PH of a sensor chip 1H as Modification Example H. An inter-pixel light-shielding film 33A closest to an outer periphery of the pixel array (positioned in the −X direction as viewed from the outer peripheral pixel PH) of the inter-pixel light-shielding film 33 provided in the outer peripheral pixel PH is provided to allow a width W33A thereof to be larger than the inter-pixel light-shielding film 33 of the middle pixel. In the sensor chip 1H, the width W33A of the inter-pixel light-shielding film 33A closest to the outer periphery of the pixel array is changed stepwise from the middle pixel toward the outer peripheral pixel PH. In the outer peripheral pixel PH, the on-chip lens 34 is not shifted in the X direction. Except for those described above, the sensor chip 1H has configurations similar to those of the sensor chip 1.

As illustrated in FIG. 15, in the outer peripheral pixel PH of the sensor chip 1H, it is possible for the inter-pixel light-shielding film 33A to block a portion of the incident light L obliquely entering the light incident surface 10A. Light entering at a position distant from the multiplication region MR is blocked by the inter-pixel light-shielding film 33A. This enables selective incidence of light entering at a position close to the multiplication region MR. The inter-pixel light-shielding film 33A may also be said to condense light to the position close to the multiplication region MR, and thus corresponds to one of the “light-condensing section” of the present disclosure. Blocking the light entering at the position distant from the multiplication region MR allows for suppression of the jitter and the crosstalk.

Similarly to the sensor chip 1, it is possible to suppress the jitter and the crosstalk in the outer peripheral pixel PH of the sensor chip 1H, thereby making it possible to equalize the characteristics of the middle pixel and the outer peripheral pixel of the pixel array.

### Modification Example I

In the above-described sensor chip 1, the on-chip lens 34 of the middle pixel P1 and the on-chip lens 34 of the outer peripheral pixel P2 are each a single-layer lens, but the present disclosure is not limited thereto; there may be a stacked structure of an inner lens 36 facing the light incident surface 10A of the SPAD 2 and an outer lens 38 provided, as a layer, above the inner lens 36. The stacked structure of the inner lens 36 and the outer lens 38 corresponds to another specific example of the “light-condensing section” of the present disclosure.

FIG. 16 illustrates an example of a cross-sectional configuration of a middle pixel PI1 of a sensor chip 1I as Modification Example I. The inner lens 36, a planarizing layer 37, and the outer lens 38 are stacked in order to be opposed to the light incident surface 10A of the SPAD 2. Except for those described above, the middle pixel PI1 of the sensor chip 1I has configurations similar to those of the middle pixel P1 of the sensor chip 1.

FIG. 17 illustrates an example of a cross-sectional configuration of an outer peripheral pixel PI2 of the sensor chip 1I. Similarly to the middle pixel PI1, the inner lens 36, the planarizing layer 37, and the outer lens 38 are stacked in order to be opposed to the light incident surface 10A of the SPAD 2. In FIG. 17, the position of the inner lens 36 relative to the SPAD 2 in the middle pixel PI1 is indicated by a dotted line 36i. In the outer peripheral pixel PI2 positioned in the −X direction as viewed from the middle pixel PI1, the inner lens 36 is provided at a position shifted in the X direction from the dotted line 34i. In the sensor chip 1I, the position of the inner lens 36 is changed stepwise from the middle pixel PI1 toward the outer peripheral pixel PI2. Except for those described above, the sensor chip 1I has configurations similar to those of the sensor chip 1.

In the outer peripheral pixel PI2 of the sensor chip 1I, the position of the inner lens 36 is shifted in the X direction, thereby correcting an optical path of the incident light L to allow the incident light obliquely entering the light incident surface 10A to be close to the multiplication region MR, thus making it possible to improve the PDE. The adjustment of the position of the inner lens 36 has a significant influence on the optical path of the incident light L; a magnitude of the shift of the inner lens 36 of the outer peripheral pixel PI2 is able to be suppressed to be smaller than a magnitude of the shift of the on-chip lens 34 of the outer peripheral pixel P2 of the sensor chip 1. This makes it possible to obtain the effects without shifting the inner lens 36 to a location above the inter-pixel light-shielding film 33.

Similarly to the sensor chip 1, it is possible to improve the PDE in the outer peripheral pixel PI2 of the sensor chip 1I. In addition, it is possible to suppress the jitter and the crosstalk, thereby making it possible to equalize the characteristics of the middle pixel and the outer peripheral pixel of the pixel array.

### Modification Example J

In the above-described sensor chip 1I, sizes of the inner lens 36 of the middle pixel PI1 and the inner lens 36 of the outer peripheral pixel PI2 are the same, but the present disclosure is not limited thereto; a width W36 of the inner lens 36 in the direction parallel to the light incident surface 10A may be changed stepwise from the middle pixel PI1 toward the outer peripheral pixel PI2.

FIG. 18 illustrates an example of a cross-sectional configuration of an outer peripheral pixel PJ of a sensor chip 1J as Modification Example J. The inner lens 36 of the outer peripheral pixel PJ is provided to allow the width W36 in the direction parallel to the light incident surface 10A to be smaller than the inner lens 36 of the middle pixel. In the sensor chip 1J, the width W36 of the inner lens 36 in the direction parallel to the light incident surface 10A is changed stepwise from the middle pixel toward the outer peripheral pixel PJ. In the outer peripheral pixel PJ, the inner lens 36 is not shifted in the X direction. Except for those described above, the sensor chip 1J has configurations similar to those of the sensor chip 1I.

In the outer peripheral pixel PJ of the sensor chip 1J, the width of the inner lens 36 is adjusted to be small, thereby correcting an optical path of the incident light L to allow the incident light obliquely entering the light incident surface 10A to be close to the multiplication region MR, thus making it possible to improve the PDE.

Similarly to the sensor chip 1I, it is possible to improve the PDE in the outer peripheral pixel PJ of the sensor chip 1J. In addition, it is possible to suppress the jitter and the crosstalk, thereby making it possible to equalize the characteristics of the middle pixel and the outer peripheral pixel of the pixel array.

### Modification Example K

In the above-described sensor chip 1I, sizes of the inner lens 36 of the middle pixel PI1 and the inner lens 36 of the outer peripheral pixel PI2 are the same, but the present disclosure is not limited thereto; a curvature of the inner lens 36 may be changed stepwise from the middle pixel PI1 toward the outer peripheral pixel PI2.

FIG. 19 illustrates an example of a cross-sectional configuration of an outer peripheral pixel PK of a sensor chip 1K as Modification Example K. The inner lens 36 of the outer peripheral pixel PK is provided to allow the curvature thereof to be smaller than that of the inner lens 36 of the middle pixel. In the sensor chip 1K, the curvature of the inner lens 36 is changed stepwise from the middle pixel toward the outer peripheral pixel PK. In the outer peripheral pixel PK, the inner lens 36 is not shifted in the X direction. Except for those described above, the sensor chip 1K has configurations similar to those of the sensor chip 1I.

In the outer peripheral pixel PK of the sensor chip 1K, the curvature of the inner lens 36 is adjusted to be small, thereby correcting an optical path of the incident light L to allow the incident light obliquely entering the light incident surface 10A to be close to the multiplication region MR, thus making it possible to improve the PDE.

Similarly to the sensor chip 1I, it is possible to improve the PDE in the outer peripheral pixel PK of the sensor chip 1K. In addition, it is possible to suppress the jitter and the crosstalk, thereby making it possible to equalize the characteristics of the middle pixel and the outer peripheral pixel of the pixel array.

### Modification Example L

In the above-described sensor chip 1I, sizes of the inner lens 36 of the middle pixel PI1 and the inner lens 36 of the outer peripheral pixel PI2 are the same, but the present disclosure is not limited thereto; a height H36 of the inner lens 36 may be changed stepwise from the middle pixel PI1 toward the outer peripheral pixel PI2.

FIG. 20 illustrates an example of a cross-sectional configuration of an outer peripheral pixel PL of a sensor chip 1L as Modification Example L. The inner lens 36 of the outer peripheral pixel PL is provided to allow the height H36 thereof to be lower than the inner lens 36 of the middle pixel. In the sensor chip 1L, the height H36 of the inner lens 36 is changed stepwise from the middle pixel toward the outer peripheral pixel PL. In the outer peripheral pixel PL, the inner lens 36 is not shifted in the X direction. Except for those described above, the sensor chip 1L has configurations similar to those of the sensor chip 1I.

In the outer peripheral pixel PL of the sensor chip 1L, the height of the inner lens 36 is adjusted to be low, thereby correcting an optical path of the incident light L to allow the incident light obliquely entering the light incident surface 10A to be close to the multiplication region MR, thus making it possible to improve the PDE.

Similarly to the sensor chip 1I, it is possible to improve the PDE in the outer peripheral pixel PL of the sensor chip 1L. In addition, it is possible to suppress the jitter and the crosstalk, thereby making it possible to equalize the characteristics of the middle pixel and the outer peripheral pixel of the pixel array.

### Modification Example M

In the above-described sensor chip 1, the light incident surface 10A of each of the middle pixel P1 and the outer peripheral pixel P2 is a flat surface, but the present disclosure is not limited thereto. Uneven shapes 50 and 51 that diffuse the incident light L may be provided on the light incident surface 10A of the SPAD 2, and the number of the uneven shapes 50 and 51 may be changed stepwise from a middle pixel PM1 to an outer peripheral pixel PM2. The uneven shapes 50 and 51 correspond to another specific example of the “light-condensing section” of the present disclosure.

FIG. 21 illustrates an example of a cross-sectional configuration of the middle pixel PM1 of a sensor chip 1M as Modification Example M. The uneven shape 50 is provided on the light incident surface 10A of the SPAD 2. In the uneven shape 50, for example, quadrangular pyramid concave shapes (inverted pyramid shapes) are arranged in array. The uneven shape 50 diffuses the incident light L by diffraction and irregular reflection. Diffusing the incident light L extends an optical path length inside the SPAD 2, thus making it possible to improve the PDE. Extending the optical path length of the incident light L increases a chance of the incident light L being detected in the multiplication region MR, and thus the uneven shape 50 may also be said to condense light to the multiplication region MR, and corresponds to one of the “light-condensing section” of the present disclosure. The uneven shape 50 is formed, for example, by conducting etching processing on the light incident surface 10A of the semiconductor substrate 10. Except for those described above, the middle pixel PM1 of the sensor chip 1M has configurations similar to those of the middle pixel P1 of the sensor chip 1.

FIG. 22 illustrates an example of a cross-sectional configuration of the outer peripheral pixel PM2 of the sensor chip 1M. Similarly to the middle pixel PM1, the uneven shape 51 is provided on the light incident surface 10A of the SPAD 2, but the number of the uneven shape 51 of the outer peripheral pixel PM2 is configured to be greater than the number of the uneven shape 50 of the middle pixel PM1. In the sensor chip 1M, the number of the uneven shape 51 is changed stepwise from the middle pixel PM1 toward the outer peripheral pixel PM2. Sizes of the uneven shape 50 of the middle pixel PM1 and the uneven shape 51 of the outer peripheral pixel PM2 are the same. In the outer peripheral pixel PM2, the on-chip lens 34 is not shifted in the X direction. Except for those described above, the sensor chip 1M has configurations similar to those of the sensor chip 1.

In the outer peripheral pixel PM2 of the sensor chip 1M, the effects of the diffusion by the uneven shape 51 is larger than those in the middle pixel PM1, and an optical path of the incident light L is corrected to be longer so as to increase a chance that the incident light obliquely entering the light incident surface 10A may be close to the multiplication region MR, thus making it possible to improve the PDE.

Similarly to the sensor chip 1, it is possible to improve the PDE in the outer peripheral pixel PM2 of the sensor chip 1M. In addition, it is possible to suppress the jitter and the crosstalk, thereby making it possible to equalize the characteristics of the middle pixel and the outer peripheral pixel of the pixel array.

### Modification Example N

Sizes of the uneven shape 50 of the light incident surface 10A of the middle pixel PM1 and the uneven shape 51 of the light incident surface 10A of the outer peripheral pixel PM2 are the same in the above-described sensor chip 1M, but the present disclosure is not limited thereto; the sizes of the uneven shapes 50 and 51 may be changed stepwise from the middle pixel PM1 toward the outer peripheral pixel PM2.

FIG. 23 illustrates an example of a cross-sectional configuration of an outer peripheral pixel PN of a sensor chip 1N as Modification Example N. An uneven shape 52 of the outer peripheral pixel PN is configured to be larger than the uneven shape 50 of the middle pixel. In the sensor chip 1N, the size of the uneven shape 52 is changed stepwise from the middle pixel toward the outer peripheral pixel PN. The number of the uneven shape 50 of the middle pixel and the number of the uneven shape 52 of the outer peripheral pixel PN are the same. Except for those described above, the sensor chip 1N has configurations similar to those of the sensor chip 1M.

In the outer peripheral pixel PN of the sensor chip 1N, the effects of the diffusion by the uneven shape 52 is larger than those in the middle pixel, and an optical path of the incident light L is corrected to be longer so as to increase a chance that the incident light obliquely entering the light incident surface 10A may be close to the multiplication region MR, thus making it possible to improve the PDE.

Similarly to the sensor chip 1M, it is possible to improve the PDE in the outer peripheral pixel PN of the sensor chip 1N. In addition, it is possible to suppress the jitter and the crosstalk, thereby making it possible to equalize the characteristics of the middle pixel and the outer peripheral pixel of the pixel array.

### Modification Example O

Positions of the light reflective film 21 of the middle pixel P1 and the light reflective film 21 of the outer peripheral pixel P2 are the same in the above-described sensor chip 1, but the present disclosure is not limited thereto; the position of the light reflective film 21 may be changed stepwise from the middle pixel P1 toward the outer peripheral pixel P2. The light reflective film 21 corresponds to another specific example of the “light-condensing section” of the present disclosure.

FIG. 24 illustrates an example of a planar configuration of a sensor chip 1O as Modification Example O. The sensor chip 1O includes the pixel array AR in which the plurality of pixels P are arranged in array. Each of pixels PO includes the light reflective film 21. In FIG. 24, the inter-pixel light-shielding film 33 and the on-chip lens 34 are omitted to illustrate a layout of the pixel PO and the light reflective film 21, and the position of the light reflective film 21 buried in each pixel PO is indicated by a dotted line. The sensor chip 1O includes a middle pixel PO1 disposed in the middle of the pixel array AR and outer peripheral pixels P02, P03, and P04 disposed on the outer periphery.

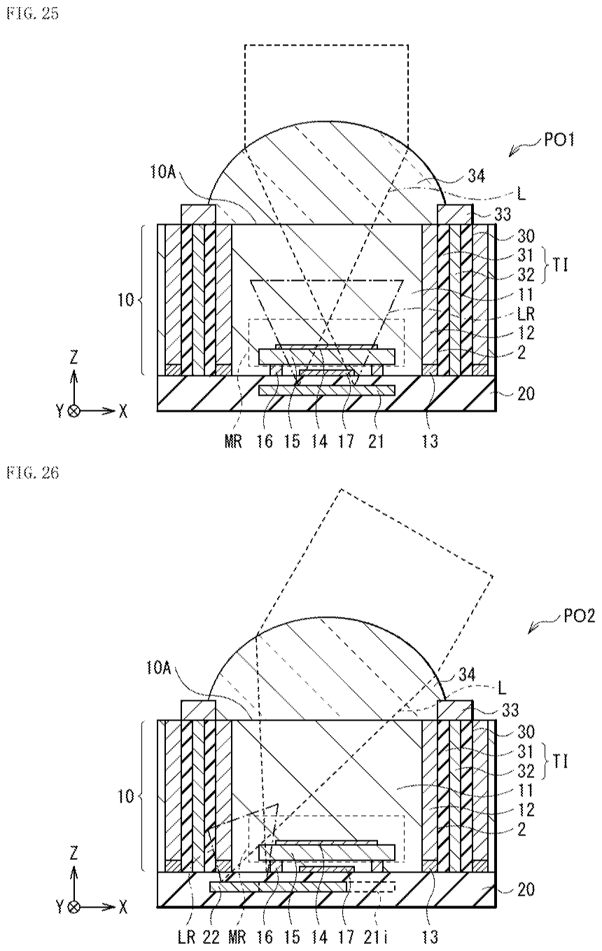

FIG. 25 illustrates an example of a cross-sectional configuration of the middle pixel PO1 of the sensor chip 1O. The middle pixel PO1 has configurations similar to those of the middle pixel P1 of the sensor chip 1. The light reflective film 21 is buried inside the wiring layer 20 provided on the front surface of the semiconductor substrate 10. The incident light L having passed through the SPAD 2 and having reached the side of the front surface of the semiconductor substrate 10 is configured to be reflected at the light reflective film 21 to be reflected light LR and to pass through the SPAD 2 again.

FIG. 26 illustrates an example of a cross-sectional configuration of the outer peripheral pixel P02 of the sensor chip 1O. A light reflective film 22 is buried inside the wiring layer 20 provided on the front surface of the semiconductor substrate 10. In FIG. 26, the position of the light reflective film 21 in the middle pixel PO1 is indicated by a dotted line 21i. In the outer peripheral pixel P02 positioned in the −X direction as viewed from the middle pixel PO1, the light reflective film 22 is provided at a position shifted in the −X direction from the dotted line 21i. In the sensor chip 1O, the position of the light reflective film 22 is changed stepwise from the middle pixel PO1 toward the outer peripheral pixel P02. In the outer peripheral pixel P02, the on-chip lens 34 is not shifted in the X direction. In addition, as illustrated in FIG. 24, in the outer peripheral pixel P03 positioned in the Y direction as viewed from the middle pixel PO1, the light reflective film 22 is provided at a position shifted in the Y direction. In the outer peripheral pixel P04 positioned in the (−X, Y) directions as viewed from the middle pixel PO1, the light reflective film 22 is provided at a position shifted in the (−X, Y) directions. Except for those described above, the sensor chip 1O has configurations similar to those of the sensor chip 1.

In the outer peripheral pixel P02, the incident light L obliquely entering the light incident surface 10A is condensed to a location deviated in the −X direction in the SPAD 2. For this reason, the incident light L having passed through the SPAD 2 reaches the side of the front surface of the semiconductor substrate 10 at a portion deviated in the −X direction in the SPAD 2. In a case where the position of the light reflective film 22 is not shifted in the −X direction, the incident light L results in going through to the outside of the SPAD 2. In the outer peripheral pixel P02, the position of the light reflective film 22 is shifted in the −X direction, thus making it possible to reflect the incident light L having reached the side of the front surface of the semiconductor substrate 10 at the portion deviated in the −X direction in the SPAD 2. The reflected light LR at the light reflective film 22 passes through the SPAD 2 again, thereby improving the PDE. The incident light L is reflected to the multiplication region MR, and thus the light reflective film 21 may also be said to condense light to the multiplication region MR, and corresponds to one of the “light-condensing section” of the present disclosure.

Similarly to the sensor chip 1, it is possible to improve the PDE in the outer peripheral pixel P02 of the sensor chip 1O. In addition, it is possible to suppress the jitter and the crosstalk, thereby making it possible to equalize the characteristics of the middle pixel and the outer peripheral pixel of the pixel array.

### Modification Example P

In the above-described sensor chip 1O, the position of the light reflective film 21 of the outer peripheral pixel P02 is changed from the position of the light reflective film 21 of the middle pixel PO1, but the present disclosure is not limited thereto; a width W23 of a light reflective film 23 in the direction parallel to the light incident surface 10A may be changed stepwise from the middle pixel PO1 toward the outer peripheral pixel P02.

FIG. 27 illustrates an example of a cross-sectional configuration of an outer peripheral pixel PP of a sensor chip 1P. The light reflective film 23 is buried inside the wiring layer 20 provided on the front surface of the semiconductor substrate 10. In FIG. 27, the position of the light reflective film 21 in the middle pixel is indicated by the dotted line 21i. In the outer peripheral pixel PP positioned in the −X direction as viewed from the middle pixel, the width W23 of the light reflective film 23 is expanded in the −X direction from the dotted line 21i. In the sensor chip 1P, the width W23 of the light reflective film 23 is changed stepwise from the middle pixel toward the outer peripheral pixel PP. Except for those described above, the sensor chip 1P has configurations similar to those of the sensor chip 1O.

In the outer peripheral pixel PP, the light reflective film 23 is provided to allow the width thereof to be expanded in the −X direction, thus making it possible to reflect the incident light L having reached the side of the front surface of the semiconductor substrate 10 at a portion deviated in the −X direction in the SPAD 2. The reflected light LR at the light reflective film 23 passes through the SPAD 2 again, thereby improving the PDE.

Similarly to the sensor chip 1, it is possible to improve the PDE in the outer peripheral pixel PP of the sensor chip 1P. In addition, it is possible to suppress the jitter and the crosstalk, thereby making it possible to equalize the characteristics of the middle pixel and the outer peripheral pixel of the pixel array.

### 3. Second Embodiment

### [Configuration Example of Sensor Chip 5]

FIG. 28A illustrates an example of a cross-sectional configuration of a sensor chip 5 according to a second embodiment. The sensor chip 5 of the present embodiment has a configuration in which the structure of the SPAD 2 of each pixel P is changed stepwise from the middle part 3 toward the outer peripheral part 4 of the pixel array AR in which the plurality of pixels P are arranged in array. Specifically, the position of the multiplication region MR is changed stepwise from the middle part 3 toward the outer peripheral part 4. Hereinafter, description is given, as an example, of the sensor chip 5 of the present embodiment by referring to the pixel (middle pixel P1) disposed in the middle part 3 of the pixel array AR and a pixel (an outer peripheral pixel P5) disposed in the outer peripheral part 4 of the pixel array AR. Although FIG. 28A illustrates the middle pixel P1 and the outer peripheral pixel P5 side by side, which are disposed at distant positions in the sensor chip 5, the intermediate pixel P is disposed between the middle pixel P1 and the outer peripheral pixel P5.

The middle pixel P1 has configurations similar to those of the middle pixel P1 of the sensor chip 1 of the first embodiment, and thus the description thereof is omitted. FIG. 28B illustrates the outer peripheral pixel P5 of FIG. 28A in an enlarged manner, and illustrates an example of a cross-sectional configuration of the outer peripheral pixel P5 of the sensor chip 5. In FIG. 28B, a position of the n-type semiconductor region 15 in the SPAD 2 in the middle pixel P1 is indicated by a dotted line 15i. In the outer peripheral pixel P5, the position of the multiplication region MR (positions of a p-type semiconductor region 14A and an n-type semiconductor region 15A) inside the SPAD 2 is shifted in the −X direction relative to the middle pixel P1, and is further shifted in a direction (a Z direction) away from the front surface of the semiconductor substrate 10. The position of the multiplication region MR (positions of the p-type semiconductor region 14A and the n-type semiconductor region 15A) is changed stepwise from the middle pixel P1 toward the outer peripheral pixel P5. A cathode 16A is formed to be coupled to the n-type semiconductor region 15A. The p-type semiconductor region 17A is shifted in the −X direction. In this manner, the position of the multiplication region MR is changed stepwise from the middle pixel toward the outer peripheral pixel P5 in the sensor chip 5. In the outer peripheral pixel P5, the on-chip lens 34 is not shifted in the X direction. Except for those described above, the sensor chip 5 has configurations similar to those of the sensor chip 1.

### [Manufacturing Method of Sensor Chip 5]

Next, description is given of a manufacturing method of the sensor chip 5. FIG. 29 illustrates an example of a manufacturing process of the middle pixel and the outer peripheral pixel P5 of the sensor chip 5. In a formation region R1 of the middle pixel of the semiconductor substrate 10, there are formed, on the front surface of the semiconductor substrate 10, a resist mask M5 having an opening with an opening width W1 at a position corresponding to an ion injection region, and a resist mask M6 with a thickness T1 covering the position corresponding to the ion injection region. In addition, in a formation region R2 of the outer peripheral pixel P5 of the semiconductor substrate 10, there are formed, on the front surface of the semiconductor substrate 10, a resist mask M7 having an opening with an opening width W2 at a position corresponding to an ion injection region, and a resist mask M8 with a thickness T2 covering the position corresponding to the ion injection region. Controlling the opening width W1 of the resist mask M5 and the opening width W2 of the resist mask M7 makes it possible to control the thickness T1 of the resist mask M6 and the thickness T2 of the resist mask M8 to each have a desired thickness by means of micro-loading effects. Next, in the formation region R1 of the middle pixel, ion injection through the resist mask M6, of which the thickness is controlled as described above, allows for respective formations of the well layer 11, the pinning layer 12, the anode 13, the p-type semiconductor region 14, the n-type semiconductor region 15, the cathode 16, and the p-type semiconductor region 17. Simultaneously with the above-described ion injection, the well layer 11, the pinning layer 12, the anode 13, the p-type semiconductor region 14A, the n-type semiconductor region 15A, the cathode 16A, and the p-type semiconductor region 17A are respectively formed in the formation region R2 of the outer peripheral pixel P5, through the resist mask M8, of which the thickness is controlled as described above. A magnitude of the ion injection energy and the thicknesses of the resist masks M6 and M8 enable a depth of ion injection to be controlled. Configurations of the well layer 11, the pinning layer 12, and the anode 13 are common between the middle pixel and the outer peripheral pixel P5, and thus the ion injection may be performed through resist masks having common thickness instead of the above-described resist masks having different thicknesses. In subsequent steps, manufacturing is able to be performed similarly to that of the sensor chip 1.

In the manufacturing method of the sensor chip 5 described above, the resist masks M6 and M8 having different thicknesses are formed, respectively, in the formation region R1 of the middle pixel and the formation region R2 of the outer peripheral pixel P5, and the ion injection is performed simultaneously in the formation region R1 of the middle pixel and the formation region R2 of the outer peripheral pixel P5. However, the ion injection may be performed in separate steps, respectively, in the formation region R1 of the middle pixel and the outer peripheral pixel P5. In this case, a resist mask having a common configuration is able to be used in the formation region R1 of the middle pixel and the formation region R2 of the outer peripheral pixel P5.

### [Operation of Sensor Chip 5]

Similarly to the sensor chip 1, in the middle pixel of the sensor chip 5, application of a large negative voltage to the anode 13, the pinning layer 12, and the p-type semiconductor region 14 causes a depletion layer to be spread from a p-n junction between the p-type semiconductor region 14 and the n-type semiconductor region 15 to form a high electric field region. In addition, similarly, in the outer peripheral pixel P5, application of a large negative voltage to the anode 13, the pinning layer 12, and the p-type semiconductor region 14A causes a depletion layer to be spread from a p-n junction between the p-type semiconductor region 14A and the n-type semiconductor region 15A to form a high electric field region. The resulting high electric field region allows for formation of the multiplication region MR that is able to avalanche-multiply carriers; carriers generated by a single photon incident from the light incident surface 10A are multiplied to generate signal charges. The sensor chip 5 is able to be used as a ToF method-based distance measurement sensor that acquires signal delay time between a signal by signal charges and a reference signal to measure a distance to a measurement target.

### [Workings and Effects of Sensor Chip 5]

As illustrated in FIGS. 28A and 28B, in the outer peripheral pixel P5 of the sensor chip 5, the position of the multiplication region MR is shifted in the −X direction and in the Z direction. For this reason, it is possible to cause the multiplication region MR to be close to a region where the incident light L is condensed by the on-chip lens 34. This allows for improvement in the PDE as well as suppression of the jitter.

Similarly to the sensor chip 1, it is possible to improve the PDF in the outer peripheral pixel P5 of the sensor chip 5. In addition, it is possible to suppress the jitter, thereby making it possible to equalize the characteristics of the middle pixel and the outer peripheral pixel of the pixel array.

### 4. Modification Examples of Second Embodiment

Hereinafter, description is given of modification examples of the sensor chip 5 according to the foregoing second embodiment. It is to be noted that, in the following modification examples, components common to those of the foregoing second embodiment are denoted with the same reference numerals.

### Modification Example Q

In the above-described sensor chip 5, only the well layer 11 is provided between the pinning layer 12 and the n-type semiconductor region 15A provided to allow the position thereof to be changed stepwise from the middle pixel toward the outer peripheral pixel, but the present disclosure is not limited thereto; an electric field relaxation layer 18 may be provided between the n-type semiconductor region 15A and the pinning layer 12.

FIG. 30 illustrates an example of a cross-sectional configuration of an outer peripheral pixel PQ of a sensor chip 5Q as Modification Example Q. Similarly to the sensor chip 5, the position of the multiplication region MR is changed stepwise from the middle pixel toward the outer peripheral pixel PQ. In addition, the electric field relaxation layer 18 is provided between the n-type semiconductor region 15A and the pinning layer 12. The electric field relaxation layer 18 is formed by an n-type semiconductor region, for example. A concentration of n-type impurities contained in the electric field relaxation layer 18 is set lower than that of the n-type semiconductor region 15A, for example. The concentration of the n-type impurities contained in the electric field relaxation layer 18 may be changed stepwise from the middle pixel toward the outer peripheral pixel PQ, or may be the same from the middle pixel toward the outer peripheral pixel PQ. Except for those described above, the sensor chip 5Q has configurations similar to those of the sensor chip 5.

When the n-type semiconductor region 15A and the pinning layer 12 are brought into close proximity to each other, electric field intensity therebetween is increased, which may possibly cause breakdown. However, the electric field relaxation layer 18 is provided in an outer peripheral pixel PR of a sensor chip 1R, thus making it possible to prevent the breakdown between the n-type semiconductor region 15A and the pinning layer 12.

Similarly to the sensor chip 5, it is possible to improve the PDE in the outer peripheral pixel PQ of the sensor chip 5Q. In addition, it is possible to suppress the jitter, thereby making it possible to equalize the characteristics of the middle pixel and the outer peripheral pixel of the pixel array.

### Modification Example R

The above-described sensor chip 5 has a configuration in which the position of the multiplication region MR is changed from the middle pixel toward the outer peripheral pixel P5, but the present disclosure is not limited thereto. For example, there may a configuration in which an electric field adjusting impurity region 19A where the concentration is changed stepwise from the middle pixel toward the outer peripheral pixel PR is provided inside the SPAD 2, instead of the position of the multiplication region MR being changed.

FIG. 31 illustrates an example of a cross-sectional configuration of the outer peripheral pixel PR of a sensor chip 5R as Modification Example R. The electric field adjusting impurity region 19A is provided inside the SPAD 2 of the outer peripheral pixel PR. The electric field adjusting impurity region 19A is, for example, an n-type semiconductor region. The electric field adjusting impurity region 19A is positioned to be spaced in the −X direction and in the Z direction as viewed from the multiplication region MR. A concentration of impurities in the electric field adjusting impurity region 19A is changed stepwise from the middle pixel toward the outer peripheral pixel PR. In addition, the position of the multiplication region MR of the middle pixel and the position of the multiplication region MR of the outer peripheral pixel PR are the same. Except for those described above, the sensor chip 5R has configurations similar to those of the sensor chip 5.

In a case where the electric field adjusting impurity region 19A is not provided, generation of carriers at a position distant from the multiplication region MR results in the carriers traveling a longer distance than the shortest path to the multiplication region MR as indicated by the dotted line JT in FIG. 31, and thus the jitter is deteriorated. In the outer peripheral pixel PR of the sensor chip 5R, providing the electric field adjusting impurity region 19A allows for adjustment of an electric field gradient between the electric field adjusting impurity region 19A and the multiplication region MR, thus enabling carriers generated in the vicinity of the electric field adjusting impurity region 19A to travel immediately to the multiplication region MR. This enables suppression of the jitter in the outer peripheral pixel PR of the sensor chip 5R. In addition, this also enables improvement in the PDE as well as reduction in the crosstalk. Adjusting the concentration and position of the electric field adjusting impurity region 19A enables adjustment of the electric field gradient between the electric field adjusting impurity region 19A and the multiplication region MR.

Similarly to the sensor chip 5, it is possible to improve the PDE in the outer peripheral pixel PR of the sensor chip 5R. In addition, it is possible to suppress the jitter and the crosstalk, thereby making it possible to equalize the characteristics of the middle pixel and the outer peripheral pixel of the pixel array.

### Modification Example S

The above-described sensor chip 5R has a configuration in which the electric field adjusting impurity region 19A is provided inside the SPAD 2, but the present disclosure is not limited thereto. For example, there may a configuration in which a charge inducing impurity region 19B where the concentration is changed stepwise from the middle pixel toward the outer peripheral pixel PR is provided inside the SPAD 2, instead of the electric field adjusting impurity region 19A.

FIG. 32 illustrates an example of a cross-sectional configuration of an outer peripheral pixel PS of a sensor chip 5S as Modification Example S. The charge inducing impurity region 19B is provided inside the SPAD 2 of the outer peripheral pixel PS. The charge inducing impurity region 19B is, for example, a P-type semiconductor region. The charge inducing impurity region 19B is provided along the pinning layer 12 in the −X direction as viewed from the multiplication region MR, and is provided on side in the Z direction from the multiplication region MR. A concentration of impurities in the charge inducing impurity region 19B is changed stepwise from the middle pixel toward the outer peripheral pixel PS. In addition, the position of the multiplication region MR of the middle pixel and the position of the multiplication region MR of the outer peripheral pixel PS are the same. Except for those described above, the sensor chip 5S has configurations similar to those of the sensor chip 5R.

In a case where the charge inducing impurity region 19B is not provided, carriers generated in the vicinity of the pinning layer 12 in the −X direction as viewed from the multiplication region MR may, in some cases, pass through between the multiplication region MR and the pinning layer 12 to travel to the side of the front surface of the semiconductor substrate 10, as indicated by a dotted line CM in FIG. 32. In this case, the PDE results in being lowered. The charge inducing impurity region 19B is provided in the outer peripheral pixel PS of the sensor chip 5S, thus causing carriers to be induced toward the multiplication region MR without passing through between the multiplication region MR and the pinning layer 12. This enables improvement in the PDE in the outer peripheral pixel PS of the sensor chip 5S. In addition, this also enables reduction in the jitter and the crosstalk. Adjusting the concentration and position of the charge inducing impurity region 19B enables adjustment of a path through which carriers are induced.

Similarly to the sensor chip 5R, it is possible to improve the PDE in the outer peripheral pixel PS of the sensor chip 5S. In addition, it is possible to suppress the jitter and the crosstalk, thereby making it possible to equalize the characteristics of the middle pixel and the outer peripheral pixel of the pixel array.

### 5. Application Example

Any of the above-described sensor chips 1 and 1A to 1S (referred to typically as the sensor chip 1) is applicable, for example, to various electronic apparatuses such as a camera such as a digital still camera or a digital video camera, a mobile phone having an imaging function, or another apparatus having an imaging function.

FIG. 33 is a block diagram illustrating an example of a schematic configuration of an electronic apparatus including the sensor chip 1 according to any of the foregoing embodiments and modification examples thereof.

An electronic apparatus 201 illustrated in FIG. 33 includes an optical system 202, a shutter device 203, the sensor chip 1, a drive circuit 205, a signal processing circuit 206, a monitor 207, and a memory 208, and is able to capture a still image and a moving image.

The optical system 202 is configured by one or a plurality of lenses, and guides light (incident light) from a subject to the sensor chip 1 to form an image on a light-receiving surface of the sensor chip 1.

The shutter device 203 is disposed between the optical system 202 and the sensor chip 1, and controls periods of light irradiation and light shielding with respect to the sensor chip 1 under the control of the drive circuit 205.

The sensor chip 1 is configured by a package including the above-described sensor chip. The sensor chip 1 generates signal charges in response to light imaged on the light-receiving surface through the optical system 202 and the shutter device 203. The signal charges generated by the sensor chip 1 is outputted to the signal processing circuit 206.

The signal processing circuit 206 conducts various types of signal processing on the signal charges outputted from the sensor chip 1. An image (image data) obtained by the signal processing circuit 206 conducting the signal processing is supplied to the monitor 207 to be displayed or supplied to the memory 208 to be stored (recorded).

Also in the electronic apparatus 201 configured as described above, the application of the sensor chip 1 makes it possible to equalize the characteristics of the middle pixel and the outer peripheral pixel of the pixel array and thus to obtain a high-definition captured image.

### 6. Practical Application Example

The technology according to an embodiment of the present disclosure (present technology) is applicable to various products. For example, the technology according to an embodiment of the present disclosure may be achieved in the form of an apparatus to be mounted to a mobile body of any kind. Non-limiting examples of the mobile body may include an automobile, an electric vehicle, a hybrid electric vehicle, a motorcycle, a bicycle, any personal mobility device, an airplane, an unmanned aerial vehicle (drone), a vessel, and a robot.

FIG. 34 is a block diagram depicting an example of schematic configuration of a vehicle control system as an example of a mobile body control system to which the technology according to an embodiment of the present disclosure can be applied.

The vehicle control system 12000 includes a plurality of electronic control units connected to each other via a communication network 12001. In the example depicted in FIG. 34, the vehicle control system 12000 includes a driving system control unit 12010, a body system control unit 12020, an outside-vehicle information detecting unit 12030, an in-vehicle information detecting unit 12040, and an integrated control unit 12050. In addition, a microcomputer 12051, a sound/image output section 12052, and a vehicle-mounted network interface (I/F) 12053 are illustrated as a functional configuration of the integrated control unit 12050.

The driving system control unit 12010 controls the operation of devices related to the driving system of the vehicle in accordance with various kinds of programs. For example, the driving system control unit 12010 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like.

The body system control unit 12020 controls the operation of various kinds of devices provided to a vehicle body in accordance with various kinds of programs. For example, the body system control unit 12020 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 12020. The body system control unit 12020 receives these input radio waves or signals, and controls a door lock device, the power window device, the lamps, or the like of the vehicle.

The outside-vehicle information detecting unit 12030 detects information about the outside of the vehicle including the vehicle control system 12000. For example, the outside-vehicle information detecting unit 12030 is connected with an imaging section 12031. The outside-vehicle information detecting unit 12030 makes the imaging section 12031 image an image of the outside of the vehicle, and receives the imaged image. On the basis of the received image, the outside-vehicle information detecting unit 12030 may perform processing of detecting an object such as a human, a vehicle, an obstacle, a sign, a character on a road surface, or the like, or processing of detecting a distance thereto.

The imaging section 12031 is an optical sensor that receives light, and which outputs an electric signal corresponding to a received light amount of the light. The imaging section 12031 can output the electric signal as an image, or can output the electric signal as information about a measured distance. In addition, the light received by the imaging section 12031 may be visible light, or may be invisible light such as infrared rays or the like.

The in-vehicle information detecting unit 12040 detects information about the inside of the vehicle. The in-vehicle information detecting unit 12040 is, for example, connected with a driver state detecting section 12041 that detects the state of a driver. The driver state detecting section 12041, for example, includes a camera that images the driver. On the basis of detection information input from the driver state detecting section 12041, the in-vehicle information detecting unit 12040 may calculate a degree of fatigue of the driver or a degree of concentration of the driver, or may determine whether the driver is dozing.

The microcomputer 12051 can calculate a control target value for the driving force generating device, the steering mechanism, or the braking device on the basis of the information about the inside or outside of the vehicle which information is obtained by the outside-vehicle information detecting unit 12030 or the in-vehicle information detecting unit 12040, and output a control command to the driving system control unit 12010. For example, the microcomputer 12051 can perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like.

In addition, the microcomputer 12051 can perform cooperative control intended for automatic driving, which makes the vehicle to travel autonomously without depending on the operation of the driver, or the like, by controlling the driving force generating device, the steering mechanism, the braking device, or the like on the basis of the information about the outside or inside of the vehicle which information is obtained by the outside-vehicle information detecting unit 12030 or the in-vehicle information detecting unit 12040.

In addition, the microcomputer 12051 can output a control command to the body system control unit 12020 on the basis of the information about the outside of the vehicle which information is obtained by the outside-vehicle information detecting unit 12030. For example, the microcomputer 12051 can perform cooperative control intended to prevent a glare by controlling the headlamp so as to change from a high beam to a low beam, for example, in accordance with the position of a preceding vehicle or an oncoming vehicle detected by the outside-vehicle information detecting unit 12030.

The sound/image output section 12052 transmits an output signal of at least one of a sound and an image to an output device capable of visually or auditorily notifying information to an occupant of the vehicle or the outside of the vehicle. In the example of FIG. 34, an audio speaker 12061, a display section 12062, and an instrument panel 12063 are illustrated as the output device. The display section 12062 may, for example, include at least one of an on-board display and a head-up display.

FIG. 35 is a diagram depicting an example of the installation position of the imaging section 12031.

In FIG. 35, the imaging section 12031 includes imaging sections 12101, 12102, 12103, 12104, and 12105.

The imaging sections 12101, 12102, 12103, 12104, and 12105 are, for example, disposed at positions on a front nose, sideview mirrors, a rear bumper, and a back door of the vehicle 12100 as well as a position on an upper portion of a windshield within the interior of the vehicle. The imaging section 12101 provided to the front nose and the imaging section 12105 provided to the upper portion of the windshield within the interior of the vehicle obtain mainly an image of the front of the vehicle 12100. The imaging sections 12102 and 12103 provided to the sideview mirrors obtain mainly an image of the sides of the vehicle 12100. The imaging section 12104 provided to the rear bumper or the back door obtains mainly an image of the rear of the vehicle 12100. The imaging section 12105 provided to the upper portion of the windshield within the interior of the vehicle is used mainly to detect a preceding vehicle, a pedestrian, an obstacle, a signal, a traffic sign, a lane, or the like.

Incidentally, FIG. 35 depicts an example of photographing ranges of the imaging sections 12101 to 12104. An imaging range 12111 represents the imaging range of the imaging section 12101 provided to the front nose. Imaging ranges 12112 and 12113 respectively represent the imaging ranges of the imaging sections 12102 and 12103 provided to the sideview mirrors. An imaging range 12114 represents the imaging range of the imaging section 12104 provided to the rear bumper or the back door. A bird's-eye image of the vehicle 12100 as viewed from above is obtained by superimposing image data imaged by the imaging sections 12101 to 12104, for example.

At least one of the imaging sections 12101 to 12104 may have a function of obtaining distance information. For example, at least one of the imaging sections 12101 to 12104 may be a stereo camera constituted of a plurality of imaging elements, or may be an imaging element having pixels for phase difference detection.

For example, the microcomputer 12051 can determine a distance to each three-dimensional object within the imaging ranges 12111 to 12114 and a temporal change in the distance (relative speed with respect to the vehicle 12100) on the basis of the distance information obtained from the imaging sections 12101 to 12104, and thereby extract, as a preceding vehicle, a nearest three-dimensional object in particular that is present on a traveling path of the vehicle 12100 and which travels in substantially the same direction as the vehicle 12100 at a predetermined speed (for example, equal to or more than 0 km/hour). Further, the microcomputer 12051 can set a following distance to be maintained in front of a preceding vehicle in advance, and perform automatic brake control (including following stop control), automatic acceleration control (including following start control), or the like. It is thus possible to perform cooperative control intended for automatic driving that makes the vehicle travel autonomously without depending on the operation of the driver or the like.

For example, the microcomputer 12051 can classify three-dimensional object data on three-dimensional objects into three-dimensional object data of a two-wheeled vehicle, a standard-sized vehicle, a large-sized vehicle, a pedestrian, a utility pole, and other three-dimensional objects on the basis of the distance information obtained from the imaging sections 12101 to 12104, extract the classified three-dimensional object data, and use the extracted three-dimensional object data for automatic avoidance of an obstacle. For example, the microcomputer 12051 identifies obstacles around the vehicle 12100 as obstacles that the driver of the vehicle 12100 can recognize visually and obstacles that are difficult for the driver of the vehicle 12100 to recognize visually. Then, the microcomputer 12051 determines a collision risk indicating a risk of collision with each obstacle. In a situation in which the collision risk is equal to or higher than a set value and there is thus a possibility of collision, the microcomputer 12051 outputs a warning to the driver via the audio speaker 12061 or the display section 12062, and performs forced deceleration or avoidance steering via the driving system control unit 12010. The microcomputer 12051 can thereby assist in driving to avoid collision.

At least one of the imaging sections 12101 to 12104 may be an infrared camera that detects infrared rays. The microcomputer 12051 can, for example, recognize a pedestrian by determining whether or not there is a pedestrian in imaged images of the imaging sections 12101 to 12104. Such recognition of a pedestrian is, for example, performed by a procedure of extracting characteristic points in the imaged images of the imaging sections 12101 to 12104 as infrared cameras and a procedure of determining whether or not it is the pedestrian by performing pattern matching processing on a series of characteristic points representing the contour of the object. When the microcomputer 12051 determines that there is a pedestrian in the imaged images of the imaging sections 12101 to 12104, and thus recognizes the pedestrian, the sound/image output section 12052 controls the display section 12062 so that a square contour line for emphasis is displayed so as to be superimposed on the recognized pedestrian. The sound/image output section 12052 may also control the display section 12062 so that an icon or the like representing the pedestrian is displayed at a desired position.

The description has been given hereinabove of an example of the mobile body control system to which the technology according to an embodiment of the present disclosure may be applied. The technology according to an embodiment of the present disclosure may be applied to the imaging section 12031 out of the configurations described above. Specifically, the sensor chip 1 according to any of the foregoing embodiments and modification examples thereof is applicable to the imaging section 12031. Applying the technology according to an embodiment of the present disclosure to the imaging section 12031 makes it possible to equalize the characteristics of the middle pixel and the outer peripheral pixel of the pixel array and thus to obtain a high-definition captured image, thus enabling high-precision control utilizing the captured image to be performed in the mobile body control system.

### 7. Other Modification Examples

The description has been given of the present disclosure with reference to the embodiments and Modification Examples A to S thereof, the application example, and the practical application example, but the present disclosure is not limited to the foregoing embodiments and the like, and may be modified in a variety of ways.

In the foregoing embodiments and modification examples, the description has been given of the example in which the middle part of the pixel array AR is one middle pixel and the outer peripheral part is one outer peripheral pixel; however, this is not limitative. Alternatively, the present disclosure is also applicable to a sensor chip having a configuration in which the middle part is a plurality of pixels arranged in the middle region of the pixel array AR. In addition, the present disclosure is also applicable to a sensor chip having a configuration in which the outer peripheral part is a plurality of pixels arranged in the outer peripheral region of the pixel array AR. Further, there may be a configuration in which at least one of a structure of the light-condensing section, an internal structure of the photoelectric conversion section, or a structure of a light-reflective section is changed stepwise for each of the plurality of pixels (or each of pixels in a plurality of columns). FIGS. 1 and 24 illustrate a pixel array including 25 pixels P in five rows×five columns, but this is merely exemplary; the number of the rows of the pixels P included in the pixel array, the number of the columns of the pixels P, and the number of the pixels P are not particularly limited. The embodiments and Modification Examples A to S thereof may be combined as appropriate.

It is to be noted that the effects described herein are merely illustrative. The effects of the present disclosure are not limited to those described herein. The present disclosure may have other effects than those described herein.

It is to be noted that the present technology may have the following configurations. According to the present technology having the following configuration, it is possible to equalize the characteristics of the middle part and the outer peripheral part of the pixel array.

(1)

A sensor chip including:

a photoelectric conversion section including a multiplication region that avalanche-multiplies carriers by a high electric field region;

a light-condensing section that condenses incident light toward the photoelectric conversion section; and

a pixel array in which a plurality of pixels each including the photoelectric conversion section and the light-condensing section are arranged in array and at least one of a structure of the photoelectric conversion section or a structure of the light-condensing section is changed stepwise from a middle part toward an outer peripheral part.

(2)

The sensor chip according to (1), in which a position of the light-condensing section relative to the photoelectric conversion section is changed stepwise from the middle part toward the outer peripheral part.

(3)

The sensor chip according to (1) or (2), in which

the light-condensing section includes an on-chip lens, and

a width of the on-chip lens in a direction parallel to a light incident surface of the photoelectric conversion section is changed stepwise from the middle part toward the outer peripheral part.

(4)

The sensor chip according to any one of (1) to (3), in which

the light-condensing section includes the on-chip lens, and

a curvature of the on-chip lens is changed stepwise from the middle part toward the outer peripheral part.

(5)

The sensor chip according to any one of (1) to (4), in which

the light-condensing section includes the on-chip lens, and

a height of the on-chip lens is changed stepwise from the middle part toward the outer peripheral part.

(6)

The sensor chip according to any one of (1) to (5), in which

the light-condensing section includes an inter-pixel light-shielding section provided between the light-condensing section and the neighboring light-condensing section, and

a width of the inter-pixel light-shielding section in the direction parallel to the light incident surface of the photoelectric conversion section is changed stepwise from the middle part toward the outer peripheral part.

(7)

The sensor chip according to any one of (1) to (6), in which the light-condensing section has a stacked structure of an inner lens facing the light incident surface of the photoelectric conversion section and an outer lens provided, as a layer, above the inner lens.

(8)

The sensor chip according to (7), in which a position of the inner lens relative to the photoelectric conversion section is changed stepwise from the middle part toward the outer peripheral part.

(9)

The sensor chip according to (7) or (8), in which a width of the inner lens in the direction parallel to the light incident surface of the photoelectric conversion section is changed stepwise from the middle part toward the outer peripheral part.

(10)

The sensor chip according to any one of (7) to (9), in which a curvature of the inner lens is changed stepwise from the middle part toward the outer peripheral part.

(11)

The sensor chip according to any one of (7) to (10), in which a height of the inner lens is changed stepwise from the middle part toward the outer peripheral part.

(12)

The sensor chip according to any one of (1) to (11), in which

an uneven shape that diffuses the incident light is formed on the light incident surface of the photoelectric conversion section, and

the number of the uneven shape is changed stepwise from the middle part toward the outer peripheral part.

(13)

The sensor chip according to any one of (1) to (12), in which

the uneven shape that diffuses the incident light is formed on the light incident surface of the photoelectric conversion section, and

a size of the uneven shape is changed stepwise from the middle part toward the outer peripheral part.

(14)

The sensor chip according to any one of (1) to (13), in which

the light-condensing section includes a light-reflective section that reflects the incident light, and a structure of the light-reflective section is changed stepwise from the middle part toward the outer peripheral part.

(15)

The sensor chip according to (14), in which a position of the light-reflective section relative to the photoelectric conversion section is changed stepwise from the middle part toward the outer peripheral part.

(16)

The sensor chip according to (14) or (15), in which a width of the light-reflective section in the direction parallel to the light incident surface of the photoelectric conversion section is changed stepwise from the middle part toward the outer peripheral part.

(17)

The sensor chip according to any one of (1) to (16), in which a position of the multiplication region in the photoelectric conversion section is changed stepwise from the middle part toward the outer peripheral part.

(18)

The sensor chip according to any one of (1) to (17), in which

the photoelectric conversion section includes an electric field adjusting impurity region, and

an amount of impurities contained in the electric field adjusting impurity region is changed stepwise from the middle part toward the outer peripheral part.

(19)

The sensor chip according to any one of (1) to (18), in which

the photoelectric conversion section includes a charge inducing impurity region, and

an amount of impurities contained in the charge inducing impurity region is changed stepwise from the middle part toward the outer peripheral part.

(20)

An electronic apparatus including:

an optical system;

a sensor chip; and

a signal processing circuit,

the sensor chip including
a photoelectric conversion section including a multiplication region that avalanche-multiplies carriers by a high electric field region,
a light-condensing section that condenses incident light toward the photoelectric conversion section, and
a pixel array in which a plurality of pixels each including the photoelectric conversion section and the light-condensing section are arranged in array and at least one of a structure of the photoelectric conversion section or a structure of the light-condensing section is changed stepwise from a middle part toward an outer peripheral part.

This application claims the benefit of Japanese Priority Patent Application JP2019-050884 filed with the Japan Patent Office on Mar. 19, 2019, the entire contents of which are incorporated herein by reference.

It should be understood by those skilled in the art that various modifications, combinations, sub-combinations, and alterations may occur depending on design requirements and other factors insofar as they are within the scope of the appended claims or the equivalents thereof.

What is claimed is:

1. A sensor chip, comprising:
a photoelectric conversion section including a multiplication region that avalanche-multiplies carriers by a high electric field region;
a light-condensing section that condenses incident light toward the photoelectric conversion section; and
a pixel array in which a plurality of pixels each including the photoelectric conversion section and the light-condensing section are arranged in array and at least one of a structure of the photoelectric conversion section or a structure of the light-condensing section is changed stepwise from a middle part toward an outer peripheral part.

2. The sensor chip according to claim 1, wherein a position of the light-condensing section relative to the photoelectric conversion section is changed stepwise from the middle part toward the outer peripheral part.

3. The sensor chip according to claim 1, wherein
the light-condensing section includes an on-chip lens, and
a width of the on-chip lens in a direction parallel to a light incident surface of the photoelectric conversion section is changed stepwise from the middle part toward the outer peripheral part.

4. The sensor chip according to claim 1, wherein
the light-condensing section includes an on-chip lens, and
a curvature of the on-chip lens is changed stepwise from the middle part toward the outer peripheral part.

5. The sensor chip according to claim 1, wherein
the light-condensing section includes an on-chip lens, and
a height of the on-chip lens is changed stepwise from the middle part toward the outer peripheral part.

6. The sensor chip according to claim 1, wherein
the light-condensing section includes an inter-pixel light-shielding section provided between the light-condensing section and the neighboring light-condensing section, and
a width of the inter-pixel light-shielding section in a direction parallel to a light incident surface of the photoelectric conversion section is changed stepwise from the middle part toward the outer peripheral part.

7. The sensor chip according to claim 1, wherein the light-condensing section has a stacked structure of an inner lens facing a light incident surface of the photoelectric conversion section and an outer lens provided, as a layer, above the inner lens.

8. The sensor chip according to claim 7, wherein a position of the inner lens relative to the photoelectric conversion section is changed stepwise from the middle part toward the outer peripheral part.

9. The sensor chip according to claim 7, wherein a width of the inner lens in a direction parallel to the light incident surface of the photoelectric conversion section is changed stepwise from the middle part toward the outer peripheral part.

10. The sensor chip according to claim 7, wherein a curvature of the inner lens is changed stepwise from the middle part toward the outer peripheral part.

11. The sensor chip according to claim 7, wherein a height of the inner lens is changed stepwise from the middle part toward the outer peripheral part.

12. The sensor chip according to claim 1, wherein
an uneven shape that diffuses the incident light is formed on a light incident surface of the photoelectric conversion section, and
the number of the uneven shape is changed stepwise from the middle part toward the outer peripheral part.

13. The sensor chip according to claim 1, wherein
an uneven shape that diffuses the incident light is formed on a light incident surface of the photoelectric conversion section, and
a size of the uneven shape is changed stepwise from the middle part toward the outer peripheral part.

14. The sensor chip according to claim 1, wherein
the light-condensing section includes a light-reflective section that reflects the incident light, and
a structure of the light-reflective section is changed stepwise from the middle part toward the outer peripheral part.

15. The sensor chip according to claim 14, wherein a position of the light-reflective section relative to the photoelectric conversion section is changed stepwise from the middle part toward the outer peripheral part.

16. The sensor chip according to claim 14, wherein a width of the light-reflective section in a direction parallel to a light incident surface of the photoelectric conversion section is changed stepwise from the middle part toward the outer peripheral part.

17. The sensor chip according to claim 1, wherein a position of the multiplication region in the photoelectric conversion section is changed stepwise from the middle part toward the outer peripheral part.

18. The sensor chip according to claim 1, wherein
the photoelectric conversion section includes an electric field adjusting impurity region, and
an amount of impurities contained in the electric field adjusting impurity region is changed stepwise from the middle part toward the outer peripheral part.

19. The sensor chip according to claim 1, wherein
the photoelectric conversion section includes a charge inducing impurity region, and
an amount of impurities contained in the charge inducing impurity region is changed stepwise from the middle part toward the outer peripheral part.

20. An electronic apparatus, comprising:
an optical system;
a sensor chip; and
a signal processing circuit,
the sensor chip including
a photoelectric conversion section including a multiplication region that avalanche-multiplies carriers by a high electric field region,
a light-condensing section that condenses incident light toward the photoelectric conversion section, and
a pixel array in which a plurality of pixels each including the photoelectric conversion section and the light-condensing section are arranged in array and at least one of a structure of the photoelectric conversion section or a structure of the light-condensing section is changed stepwise from a middle part toward an outer peripheral part.
